(19) United States
(12) Patent Application Publication
(10) Pub. No.: US 2024/0282851 A1
(43) Pub. Date: Aug. 22, 2024

(54) SEMICONDUCTOR DEVICE

(71) Applicant: ROHM CO., LTD., Kyoto-shi (JP)

(72) Inventors: Yuji OSUMI, Kyoto-shi (JP); Yoshinori FUKUDA, Kyoto-shi (JP)

(73) Assignee: ROHM CO., LTD., Kyoto-shi (JP)

(21) Appl. No.: 18/442,104

(22) Filed: Feb. 15, 2024

(30) Foreign Application Priority Data
Feb. 17, 2023 (JP) 2023-023451

(51) Int. Cl. H01L 29/78; H01L 27/06; H01L 27/088; H01L 29/10

(52) U.S. Cl. CPC H01L 29/7813; H01L 27/0629; H01L 27/088; H01L 29/1095; H01L 29/7821

(57) ABSTRACT

The present disclosure provides a semiconductor device. The semiconductor device includes a main transistor, a monitoring transistor and a pair of separation portions selectively formed in a gate space sandwiched between adjacent trench gate structures. A body region is separated into a monitoring body region sandwiched between the pair of separation portions and a main body region at an opposite side of the monitoring body region across the pair of separation portions. The trench gate structures include: a first gate structure adjacent to the monitoring body region and the main body region along a first direction; and a second gate structure adjacent to the pair of separation portions. The first gate structure is a multi-electrode structure and the second gate structure is a single-electrode structure.

### CROSS-REFERENCE TO RELATED APPLICATION

This application is based upon and claims the benefit of priority from Japanese Patent Application No. 2023-023451, filed on Feb. 17, 2023, the entire contents of which are incorporated herein by reference.

### TECHNICAL FIELD

The present disclosure relates to a semiconductor device.

### BACKGROUND

For example, patent document 1 discloses a semiconductor device including a semiconductor layer and multiple insulated gate transistors. The multiple insulated gate transistors are electrically independently formed on the semiconductor layer in a manner of being individually input with electrically independent control signals, and are individually controlled to be on/off in a manner that an on resistance during an active clamping operation is different from an on resistance during a normal operation.

### PRIOR ART DOCUMENT

### Patent Publication

[Patent document 1] Japan Patent Publication No. 2022-97649

### BRIEF DESCRIPTION OF THE DRAWINGS

FIG. 1 is a plan view of a semiconductor device according to a first embodiment.

FIG. 2 is a cross-sectional view along a section line II-II in FIG. 1.

FIG. 3 is a plan view of a layout example in a semiconductor chip in FIG. 1.

FIG. 4 is a circuit block diagram of an example of an electrical structure of the semiconductor device in FIG. 1.

FIG. 5 is an equivalent circuit diagram of a main transistor and a monitoring transistor in FIG. 4.

FIG. 6 is a further equivalent circuit diagram of a main transistor and a monitoring transistor in FIG. 5.

FIG. 7A is a circuit diagram of operation examples of a main transistor and a monitoring transistor.

FIG. 7B is a circuit diagram of operation examples of a main transistor and a monitoring transistor.

FIG. 7C is a circuit diagram of operation examples of a main transistor and a monitoring transistor.

FIG. 8 is a circuit block diagram of a configuration example of an electrical structure of the semiconductor device in FIG. 1 (equivalent to a configuration example applying a main transistor of two systems and a monitoring transistor of two systems).

FIG. 9 is a circuit diagram of a configuration example of the circuit block diagram in FIG. 8.

FIG. 10 is an enlarged diagram of a region X shown in FIG. 3, and is a plan view of a layout example of the main transistor and the monitoring transistor in FIG. 8.

FIG. 11 is an enlarged diagram of a region XI shown in FIG. 10.

FIG. 12 is an enlarged diagram of a region XII shown in FIG. 10.

FIG. 13 is a cross-sectional view along a section line XIII-XIII in FIG. 11.

FIG. 14 is a cross-sectional view along a section line XIV-XIV in FIG. 11.

FIG. 15 is a cross-sectional view along a section line XV-XV in FIG. 11.

FIG. 16 is a cross-sectional view along a section line XVI-XVI in FIG. 11.

FIG. 17 is a perspective cross-sectional view of a first configuration example showing all of a main portion of a main transistor, a first channel region and a second channel region.

FIG. 18 is a perspective cross-sectional view of a second configuration example showing all of a main portion of a main transistor, a first channel region and a second channel region.

FIG. 19 is a perspective cross-sectional view of a third configuration example showing all of a main portion of a main transistor, a first channel region and a second channel region.

FIG. 20 is a perspective cross-sectional view of a fourth configuration example showing all of a main portion of a main transistor, a first channel region and a second channel region.

FIG. 21 is a perspective cross-sectional view of the semiconductor device near a separation portion separating the main transistor and the monitoring transistor.

FIG. 22 is a schematic plan view of a planar structure near the separation portion.

FIG. 23 is a schematic plan view of a planar structure near the separation portion.

FIG. 24 is a schematic plan view of a planar structure near the separation portion.

FIG. 25 is a cross-sectional view along a section line XXV-XXV in FIG. 24.

FIG. 26 is a cross-sectional view along a section line XXVI-XXVI in FIG. 24.

FIG. 27 is a cross-sectional view along a section line XXVII-XXVII in FIG. 24.

FIG. 28 is a cross-sectional view along a section line XXVIII-XXVIII in FIG. 24.

FIG. 29 is a cross-sectional view along a section line XXIX-XXIX in FIG. 24.

FIG. 30 is a curve diagram for comparing withstand voltage performance of Samples 1 to 3.

FIG. 31 is a schematic plan view of a first variation example of the separation portion.

FIG. 32 is a schematic cross-sectional view of the first variation example of the separation portion.

FIG. 33 is a schematic plan view of a second variation example of the separation portion.

FIG. 34 is a schematic cross-sectional view of the second variation example of the separation portion.

### DETAILED DESCRIPTION OF THE EMBODIMENTS

The embodiments are described in detail with reference to the accompanying drawings below. These accompanying drawings are schematic and are not strictly depicted according to equivalent or actual scales. Moreover, corresponding structures in the accompanying drawings are denoted with the same numeral and symbols and the repeated details are omitted or simplified.

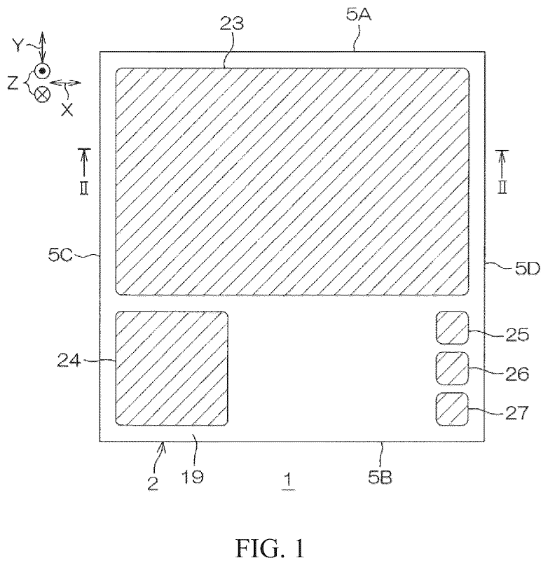

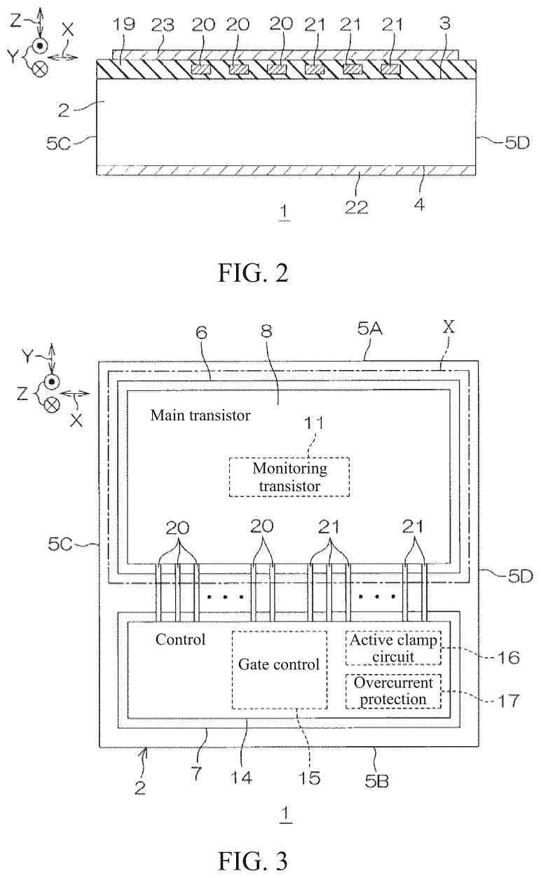

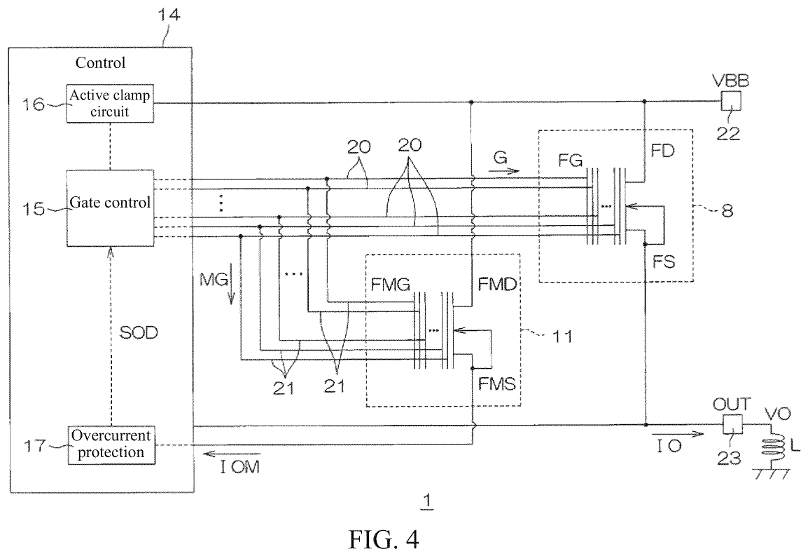

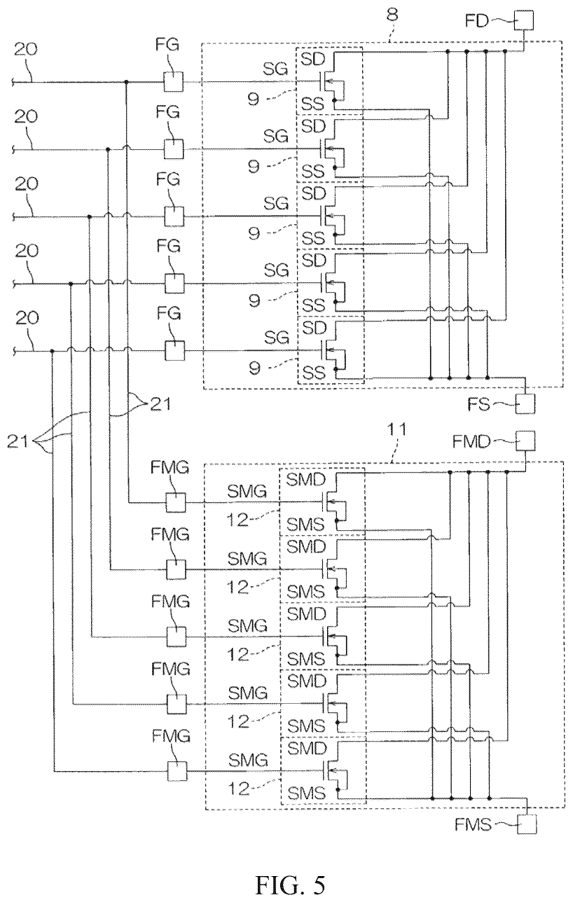

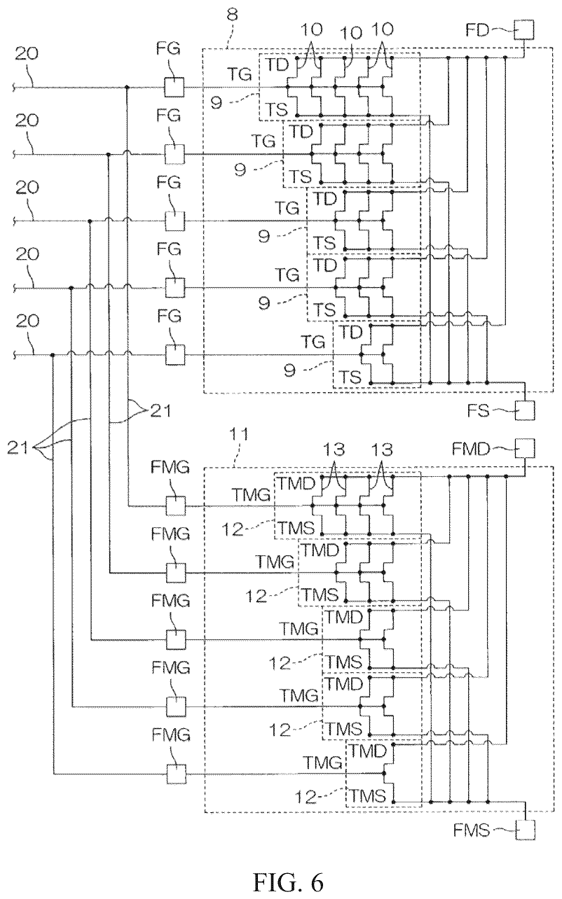

FIG. 1 shows a plan view of a semiconductor device 1 according to a first embodiment. FIG. 2 shows a cross-sectional view along a section line II-II in FIG. 1. FIG. 3 shows a plan view of a layout example in a semiconductor chip 2 in FIG. 1. FIG. 4 shows a circuit block diagram of an example of an electrical structure of the semiconductor device 1 in FIG. 1. FIG. 5 shows an equivalent circuit diagram of a main transistor 8 and a monitoring transistor 11 in FIG. 4. FIG. 6 shows a further equivalent circuit diagram of the main transistor 8 and the monitoring transistor 11 in FIG. 5. In FIG. 4, an example in which an inductive load L is externally connected to an output terminal is shown.

Referring to FIG. 1 to FIG. 2, in this embodiment, the semiconductor device 1 includes a semiconductor chip 2 formed to have a rectangular shape. The semiconductor chip 2 includes a silicon (Si) chip. The semiconductor chip 2 can also be a chip including silicon (Si) single crystals or silicon carbide (SiC) single crystals. The semiconductor chip 2 has a first main surface 3 on one side, a second main surface 4 on the other side, and first to fourth side surfaces 5A to 5D connecting the first main surface 3 and the second main surface 4. The first main surface 3 and the second main surface 4 are formed to have quadrilateral shapes in a plan view when observed in a normal direction Z thereof (hereinafter referred to as “in the plan view”).

The first main surface 3 is a device surface in which functional devices are formed. The second main surface 4 is a mounting surface, and can also include a grinding surface with grinding marks. The first to fourth side surfaces 5A to 5D include a first side surface 5A, a second side surface 5B, a third side surface 5C and a fourth side surface 5D. The first side surface 5A and the second side surface 5B extend along a first direction X of the first main surface 3, and are opposite in a second direction Y intersecting (specifically, perpendicular to) the first direction X. The third side surface 5C and the fourth side surface 5D extend along the second direction Y, and are opposite along the first direction X.

Referring to FIG. 3, the semiconductor device 1 includes a first device region 6 disposed in the first main surface 3. The first device region 6 is an output region in which output signals output to the outside are generated. In this embodiment, the first device region 6 is defined in a region on a side of the first side surface 5A in the first main surface 3. The first device region 6 can be defined to have a quadrilateral shape in the plan view, or can be defined to have a polygonal shape other than a quadrilateral shape. The configuration and planar shape of the first device region 6 can be any as desired and are not limited to any specific forms.

The semiconductor device 1 includes a second device region 7 disposed in a region different from the first device region 6 in the first main surface 3. The second device region 7 is an input region to which external electrical signals are input. In this embodiment, the second device region 7 is defined in a region on a side of the second side surface 5B with respect to the first device region 6. The second device region 7 can be defined to have a quadrilateral shape in the plan view, or can be defined o have a polygonal shape other than a quadrilateral shape. The configuration and planar shape of the second device region 7 can be any as desired and are not limited to any specific forms.

The second device region 7 preferably has a planar area less than a planar area of the first device region 6. The second device region 7 is preferably formed to have an area ratio of between about 0.1 and about 1 with respect to the first device region 6. The area ratio is a ratio of the planar area of the second device region 7 to the planar area of the first device region 6. The area ratio is preferably less than 1. As a matter of course, the second device region 7 having a planar area greater than the planar area of the first device region 6 can also be adopted.

Referring to FIG. 4, the semiconductor device 1 includes a gate-insulated main transistor 8 of n systems (n≥2) formed in the first device region 6. The main transistor 8 can also be referred to as “a gate separated transistor”, “a power transistor” or “a power metal insulator semiconductor field effect transistor (MISFET). The main transistor 8 includes n first gates FG, a first drain FD and a first source FS. The first gate FG, the first drain FD and the first source FS can also be referred to as “a main gate”, “a main drain” and “a main source”, respectively.

The same or different n gate signals G (gate voltages) are input to the n first gates FG at any desired timing. Each gate signal G includes an on signal that controls a portion of the main transistor 8 to be on, and an off signal that controls a portion of the main transistor 8 to be off. In response to the n gate signals G, the main transistor 8 generates a single output current IO (an output signal) and outputs the single output current IO from the first drain FD and the first source FS. That is, the main transistor 8 includes a multiple-input-single-output switching device. More specifically, the output current IO is a drain-source current flowing between the first drain FD and the first source FS. The output current IO is output to the outside of the first device region 6.

Referring to FIG. 5, the main transistor 8 includes n system transistors 9. The n system transistors 9 are collectively formed in one single first device region 6, and are configured to be controlled to be on and off in a manner of being electrically independent from one another. More specifically, the n system transistors 9 are connected in parallel to one another in a manner of being individually input with the n gate signals G, and form one system parallel circuit (equivalent to the main transistor 8). That is to say, the main transistor 8 of the n systems is configured to have a system transistor 9 that is on and a system transistor 9 that is off to coexist at any desired timing.

Each of the n system transistors 9 includes a second gate SG, a second drain SD and a second source SS. The second gate SG, the second drain SD and the second source SS can also be referred to as “a system gate”, “a system drain” and “a system source”, respectively. The n second gates SG are respectively connected to the n first gates FG in one-to-one correspondence. The n second drains SD are individually connected to one first drain FD. The n second sources SS are individually connected to one first source FS.

That is to say, the n second gates SG, the n second drains SD and the n second sources SS of the n system transistors 9 respectively form the n first gates FG, the one first drain FD and the one first source FS of the main transistor 8. The n first gates FG substantially include the n second gates SG.

Each of the n system transistors 9 generates a system current IS in response to the corresponding gate signal G, and respectively outputs the system current IS from the first drain FD and the first source FS. More specifically, the n system currents IS are drain-source currents flowing between the second drains SD and the second sources SS of the n system transistors 9. The n system currents IS can have different values, or can have values equal to one another. The n system currents IS are added between the first drains FD and the first sources FS. Accordingly, the one single output current IO is generated by a sum of the n system currents IS.

Referring to FIG. 6, each of the n system transistors 9 includes one or multiple unit transistors 10 that are systemized (grouped) as individual control targets. In this embodiment, each of the multiple unit transistors 10 is formed by a trench gate type. More specifically, each of the n system transistors 9 includes a unit parallel circuit formed by one or multiple unit transistors 10.

A case where the system transistor 9 formed by one unit transistor 10 also includes “the unit parallel circuit” herein. The number of the unit transistors 10 included in each system transistor 9 can be any as desired, but it is preferable that at least one system transistor 9 includes multiple unit transistors 10. The n system transistors 9 can also include the same number or different numbers of unit transistors 10.

Each of the unit transistors 10 includes a third gate TG, a third drain TD and a third source TS. The third gate TG, the third drain TD and the third source TS can also be referred to as “a unit gate”, “a unit drain” and “a unit source”, respectively. In each of the system transistors 9, all of the third gates TG of the one or multiple unit transistors 10 are electrically connected to the second gate SG, all of the third drains TD are electrically connected to the second drain SD, and all of the third sources TS are electrically connected to the second source SS. That is to say, the third gates TG, the third drains TD and the third sources TS of the systemized one or multiple unit transistors 10 form the second gate SG, the second drain SD and the second source SS of each of the system transistors 9, respectively.

Electrical characteristics of each of the system transistors 9 are adjusted according to electrical specifications of the main transistor 8 to be implemented. The electrical specifications of the main transistor 8 are, for example, channel utilization rate, on resistance and switching waveform. The term “substantially equivalent” used in the description below includes a case where a value of a measurement target and a value of a comparison target are completely consistent, and further includes a case where a value of a measurement target falls within a range between 0.9 times and 1.1 times of a value of a comparison target.

The n system transistors 9 can have a substantially equivalent gate threshold voltage or can have different gate threshold voltages. The n system transistors 9 can have a substantially equivalent channel area per unit area or can have different channel areas. That is to say, the n system transistors 9 can have a substantially equivalent on resistance characteristics or can have different on resistance characteristics.

The multiple unit transistors 10 can have a substantially equivalent gate threshold voltage or can have different gate threshold voltages. The multiple unit transistors 10 can have a substantially equivalent channel area per unit area or can have different channel areas. That is to say, the multiple unit transistors 10 can have substantially equivalent on resistance characteristics or can have different on resistance characteristics. The electrical characteristics of each of the system transistors 9 are precisely adjusted by adjusting the number, the gate threshold voltages and the channel areas of the multiple unit transistors 10.

Referring to FIG. 4, the semiconductor device 1 further includes a gate-insulated monitoring transistor 11 of m systems (m≥1) formed in the first device region 6. That is to say, the monitoring transistor 11 and the main transistor 8 are formed collectively in the one single first device region 6. In this embodiment, the monitoring transistor 11 is separated from a periphery of the first device region 6 and formed within the first device region 6, and is disposed adjacent to the main transistor 8. In this embodiment, the monitoring transistor 11 is formed within a region surrounded by the main transistor 8.

The monitoring transistor 11 can be configured to be connected in parallel with at least one system transistor 9, so as to monitor at least one system current IS. The monitoring transistor 11 preferably includes a monitoring transistor 11 configured to be connected in parallel with the multiple system transistors 9 so as to monitor multiple system currents IS of m systems (m≥2).

In this embodiment, the monitoring transistor 11 includes a monitoring transistor 11 configured to be connected in parallel with the n system transistors 9 so as to monitor n system currents IS of n systems (m=n). Optionally, the term “m system” or “m (number of)” is replaced by “n systems” or “m systems” to describe the configuration of the monitoring transistor 11 below.

In this embodiment, the monitoring transistor 11 includes n first monitoring gates FMG, a first monitoring drain FMD and a first monitoring source FMS. The first monitoring gate FMG, the first monitoring drain FMD and the first monitoring source FMS can also be referred to as “a main monitoring gate”, “a main monitoring drain” and “a main monitoring source”, respectively.

The n first monitoring gates FMG are configured to be individually input with n monitoring gate signals MG. The first monitoring drain FMD is electrically connected to the first drain FD. The first monitoring source FMS is electrically isolated from the first source FS. The same or different n monitoring gate signals MG (monitoring gate voltages) are input to the n first monitoring gates FMG at any desired timing. Each of the monitoring gate signals MG includes an on signal that controls a portion of the monitoring transistor 11 to be on, and an off signal that controls a portion of the monitoring transistor 11 to be off.

In this embodiment, in response to the n monitoring gate signals MG, the monitoring transistor 11 generates a single output monitoring current IOM (an output monitoring signal) of the n system currents IS (the output current IO), and outputs the single output monitoring current IOM from the first monitoring drain FMD and the first monitoring source FMS. That is to say, in this embodiment, the monitoring transistor 11 includes a multiple-input-single-output switching device. More specifically, the output monitoring current IOM is a drain-source current flowing between the first monitoring drain FMD and the first monitoring source FMS.

In this embodiment, the n first monitoring gates FMG are respectively electrically connected to the n corresponding first gates FG in one-to-one correspondence. Thus, the n first monitoring gates FMG are configured to be individually input with the monitoring gate signals MG including the gate signals G. That is to say, the monitoring transistor 11 and the n system transistors 9 are controlled to be on/off at the same timing, and the output monitoring current IOM that increases/decreases as the output current IO increases/decreases is generated. The output monitoring current IOM is output to a current path electrically independent from a current path of the output current IO. The output monitoring current IOM and the output current IO are electrically independent output to the outside of the first device region 6.

The output monitoring current IOM is less than or equal to the output current IO (IOM≤IO). The output monitoring current IOM is preferably less than the output current IO (IOM<IO). The output monitoring current IOM is preferably proportional to the output current IO. A current ratio IOM/IO of the output monitoring current IOM to the output current IO can be any as desired. The current ratio IOM/IO can be between about 1/10000 and about 1 (preferably less than 1).

Referring to FIG. 5, the monitoring transistor 11 includes m (n in this embodiment) system monitoring transistors 12. The number of the systems of the monitoring transistor 11 is adjusted according to the number of the system monitoring transistors 12. That is to say, when the monitoring transistor 11 of m systems (m≥1) monitors at least one system current IS, at least one system monitoring transistor 12 is electrically connected (more specifically, connected in parallel) to at least one system transistor 9. Moreover, when the monitoring transistor 11 of m systems (m≥2) monitors multiple system currents IS, multiple system monitoring transistors 12 are electrically connected to multiple system transistors 9. In this embodiment, n system monitoring transistors 12 are electrically connected to n system transistors 9.

The n system monitoring transistors 12 are configured to be collectively formed in the single first device region 6, and to be controlled to be on and off in a manner of being electrically independent from one another. More specifically, the n system monitoring transistors 12 are connected in parallel to one another in a manner of being individually input with the n monitoring gate signals MG, and form one system monitoring parallel circuit (equivalent to the monitoring transistor 11). That is to say, the monitoring transistor 11 is configured to have a system monitoring transistor 12 that is on and a system monitoring transistor 12 that is off to coexist at any desired timing.

Each of the n system monitoring transistors 12 includes a second monitoring gate SMG, a second monitoring drain SMD and a second monitoring source SMS. The second monitoring gate SMG, the second monitoring drain SMD and the second monitoring source SMS can also be referred to as “a system monitoring gate”, “a system monitoring drain” and “a system monitoring source”, respectively. The n second monitoring gates SMG are respectively connected to the n first monitoring gates FMG in one-to-one correspondence. The n second monitoring drains SMD are individually connected to one first monitoring drain FMD. The n second monitoring sources SMS are individually connected to one first monitoring source FMS.

The n second monitoring gates SMG, the n second monitoring drains SMD and the n second monitoring sources SMS of the n system monitoring transistors 12 respectively form the n first monitoring gates FMG, the one first monitoring drain FMD and the one first monitoring source FMS of the monitoring transistor 11. The n first monitoring gates FMG substantially include the n second monitoring gates SMG.

The same or different n monitoring gate signals MG are input to the n second monitoring gates SMG at any desired timing. In response to the corresponding monitoring gate signal MG, each of the n system monitoring transistors 12 generates a system monitoring current ISM (a system monitoring signal) for monitoring the system current IS of the corresponding system transistor 9, and outputs the system monitoring current ISM from the second monitoring drain SMD and the second monitoring source SMS.

More specifically, each of the system monitoring currents ISM is a drain-source current flowing between the second monitoring drain SMD and the second monitoring source SMS of each of the system monitoring transistors 12. The n system monitoring current ISM are added between the first monitoring drains FMD and the first monitoring sources FMS. Accordingly, the one single output monitoring current IO is generated by a sum of the n system monitoring currents ISM.

In this embodiment, n system monitoring transistors 12 are configured to be respectively electrically connected to corresponding system transistors 9 in one-to-one correspondence, and perform a control in conjunction with the corresponding system transistors 9. More specifically, each of the n system monitoring transistors 12 is connected in parallel with the corresponding system transistor 9, and outputs the system monitoring current ISM to a current path electrically independent from the current path of the system current IS. The n second monitoring gates SMG are respectively electrically connected to the corresponding first gates FG in one-to-one correspondence. The second monitoring drain SMD is electrically connected to the first drain FD. The second monitoring source SMS is electrically isolated from the first source FS.

That is to say, in this embodiment, the monitoring gate signals MG including the gate signals G are respectively input to the n second monitoring gates SMG. Accordingly, the n system monitoring transistors 12 and the corresponding system transistors 9 perform on/off control at the same timing, and the system monitoring currents ISM that increase/decrease as the corresponding system currents IS increase/decrease are generated. The system monitoring currents ISM and the system currents IS are electrically independently sourced from the second monitoring drains SMD and the second monitoring sources SMS.

Each of the system monitoring currents ISM is less than or equal to the corresponding system current IS (ISM≤IS). Each of the system monitoring currents ISM is preferably less than the corresponding system current IS (ISM<IS). Each of the system monitoring currents ISM is preferably proportional to the corresponding system current IS. A current ratio ISM/IS of the system monitoring current ISM to the system current IS can be any as desired. The current ratio ISM/IS can be between about 1/10000 and about 1 (preferably less than 1).

Referring to FIG. 6, each of the n system monitoring transistors 12 includes one or multiple unit monitoring transistors 13 that are systemized (grouped) as individual control targets. In this embodiment, each of the multiple unit monitoring transistors 13 includes a trench gate type. More specifically, each of the n system monitoring transistors 12 includes a unit monitoring parallel circuit formed by one or multiple unit monitoring transistors 13.

A case where the system monitoring transistor 12 formed by one unit monitoring transistor 13 also includes “the unit monitoring parallel circuit” herein. The number of the unit monitoring transistors 13 included in each of the system monitoring transistors 12 can be any as desired. The n system monitoring transistors 12 can also include the same number or different numbers of unit monitoring transistors 13. The number of the unit monitoring transistors 13 included in each of the system monitoring transistors 12 is preferably less than the number of the unit transistors 10 included in the corresponding system transistor 9. In this case, the system monitoring current ISM less than the system current IS can be more easily generated.

Each of the unit monitoring transistors 13 includes a third monitoring gate TMG, a third monitoring drain TMD and a third monitoring source TMS. The third monitoring gate TMG, the third monitoring drain TMD and the third monitoring source TMS can also be referred to as “a unit monitoring gate”, “a unit monitoring drain” and “a unit monitoring source”, respectively. In each of the system monitoring transistors 12, all of the third monitoring gates TMG of the one or multiple unit monitoring transistors 13 are electrically connected to the second monitoring gate SMG, all of the third monitoring drains TMD are electrically connected to the second monitoring drain SMD, and all of the third monitoring sources TMS are electrically connected to the second source SMS.

That is to say, the third monitoring gates TMG, the third monitoring drains TMD and the third monitoring sources TMS of the systemized one or multiple unit monitoring transistors 13 form the second monitoring gate SMG, the second monitoring drain SMD and the second monitoring source SMS of each of the system monitoring transistors 12, respectively.

Electrical characteristics of the n system monitoring transistors 12 are adjusted according to electrical specifications of the monitoring transistor 11 to be implemented. The electrical specifications of the monitoring transistor 11 are, for example, channel utilization rate, on resistance and switching waveform. The n system monitoring transistors 12 can have a substantially equivalent gate threshold voltage or can have different gate threshold voltages. The n system monitoring transistors 12 can have a substantially equivalent channel area per unit area or can have different channel areas.

That is to say, the n system monitoring transistors 12 can have substantially equivalent on resistance characteristics or can have different on resistance characteristics. The gate threshold voltage, channel area and on resistance characteristics of the n system monitoring transistors 12 can be substantially equivalent to or can be different from the gate threshold voltage, channel area and on resistance characteristics of the corresponding system transistors 9.

The multiple unit monitoring transistors 13 can have a substantially equivalent gate threshold voltage or can have different gate threshold voltages. The multiple unit monitoring transistors 13 can have a substantially equivalent channel area per unit area or can have different channel areas. That is to say, the multiple unit monitoring transistors 13 can have substantially equivalent on resistance characteristics or can have different on resistance characteristics.

The gate threshold voltage, channel area and on resistance characteristics of the unit monitoring transistors 13 included in each of the system monitoring transistors 12 can be substantially equivalent to or can be different from the gate threshold voltage, channel area and on resistance characteristics of the unit transistors 10 included in the corresponding system transistor 9. The channel area of the unit monitoring transistors 13 included in each of the system monitoring transistors 12 is preferably less than the channel area of the unit transistors 10 included in the corresponding system transistor 9. The electrical characteristics of each of the system monitoring transistors 12 are precisely adjusted by adjusting the number, the gate threshold voltages and the channel areas of the multiple unit monitoring transistors 13.

Referring to FIG. 3 and FIG. 4, the semiconductor device 1 further includes a control integrated circuit (IC) 14 as an example of a control circuit formed in the second device region 7. The control IC 14 together with the main transistor 8 and the monitoring transistor 11 form an intelligent power device (IPD). The IPD can also be referred to as an intelligent power module (IPM).

The control IC 14 includes multiple function circuits that implement various functions in response to electrical signals input from the outside. The multiple function circuits include a gate control circuit 15, an active clamp circuit 16 and an overcurrent protection circuit 17. The overcurrent protection circuit 17 can also be referred to as an “OCP circuit”. Although omitted from the drawings, the control IC 14 can also include multiple anomaly detection circuits for detecting anomalies (for example, overvoltage or overheat) of the main transistor 8, the monitoring transistor 11 and function circuits. The gate control circuit 15 is electrically connected to the first gate FG of the main transistor 8 and the first monitoring gate FMG of the monitoring circuit 11, and drives and controls the main transistor 8 and the monitoring transistor 11 in response to external electrical signals.

More specifically, the gate control circuit 15 is configured to be electrically connected to the n first gates FG (the second gates SG of the n system transistors 9) of the main transistor 8, and individually control the n first gates FG (the n system transistors 9). The gate control circuit 15 is further configured to be electrically connected to the n first monitoring gates FMG (the n second monitoring gates SMG) of the monitoring transistor 11, and individually control the n first monitoring gates FMG (the n system monitoring transistors 12). In this embodiment, the n first monitoring gates FMG (the n second monitoring gates SMG) of the monitoring transistor 11 are electrically connected to the corresponding first gates FG, respectively. Thus, the gate control circuit 15 individually controls the n first monitoring gates FMG in conjunction with the n first gates FG.

The active clamp circuit 16 is electrically connected to the main transistor 8 and the gate control circuit 15. The active clamp circuit 16 is configured to limit (clamp) an output voltage VO when a counter electromotive force due to energy accumulated in the inductive load L is input to the main transistor 8, and thus protects the main transistor 8 from being affected by the counter electromotive force. That is to say, the active clamp circuit 16 limits the output voltage VO by performing an active clamping operation by the main transistor 8 when the counter electromotive force is input, until the counter electromotive force is depleted.

More specifically, the active clamp circuit 16 is electrically connected to a portion (but not all) of the first gate FG and the first drain FD of the main transistor 8. When the active clamp circuit 16 performs the active clamping operation, a portion of the system transistors 9 are controlled to be on and the remaining system transistors 9 are controlled to be off. That is to say, during the active clamping operation, the active clamp circuit 16 increases the on resistance of the main transistor 8 to protect the main transistor 8 from being affected by the counter electromotive force.

The active clamp circuit 16 is further electrically connected to the monitoring transistor 11 and the gate control circuit 15. The active clamp circuit 16 is configured to limit (clamp) the output voltage VO when a counter electromotive force due to energy accumulated in the inductive load Lis input to the monitoring transistor 11, and thus protects the monitoring transistor 11 from being affected by the counter electromotive force. That is to say, the active clamp circuit 16 limits the output voltage VO by performing an active clamping operation by the monitoring transistor 11 when the counter electromotive force is input, until the counter electromotive force is depleted.

More specifically, the active clamp circuit 16 is electrically connected to a portion (but not all) of the first monitoring gate FMG and the first monitoring drain FMD of the monitoring transistor 11. When the active clamp circuit 16 performs the active clamping operation, a portion of the system monitoring transistors 12 are controlled to be on and the remaining system monitoring transistors 12 are controlled to be off.

More specifically, during the active clamping operation, the active clamp circuit 16 controls the monitoring transistors 11 of the n systems to be on/off in conjunction with the on/off of the main transistors 8 of the n systems. More specifically, during the active clamping operation, the active clamp circuit 16 controls the system monitoring transistor 12 corresponding to the system transistor 9 that is on to be also on, and controls the system monitoring transistor 12 corresponding to the system transistor 9 that is off to be also off.

That is to say, during the active clamping operation, the active clamp circuit 16 increases the on resistance of the monitoring transistor 11 to protect the monitoring transistor 11 from being affected by the counter electromotive force. The active clamp circuit 16 can also be configured to control the n system transistors 9 to be on/off and control the n system monitoring transistors 12 to be on/off when the first source FS of the main transistor 8 is below a predetermined voltage (for example, a predetermined negative voltage).

The overcurrent protection circuit 17 is electrically connected to the monitoring transistor 11 and the gate control circuit 15. The overcurrent protection circuit 17 is configured to be electrically connected to the first monitoring source FMS of the monitoring transistor 11, and obtain a portion or all (all in this embodiment) of the output monitoring current IOM. The overcurrent protection circuit 17 is configured to control, according to the output monitoring current IOM, the gate signals G generated by the gate control circuit 15, and limit the output current IO to be below a predetermined value, accordingly protecting the main transistor 8 from being affected by overcurrents.

The overcurrent protection circuit 17 can also be configured to obtain at least one of the multiple system monitoring currents ISM. According to a circuit configuration of the control IC 14, in the output monitoring current IOM (the multiple system monitoring currents ISM), a current input to the overcurrent protection circuit 17 is regulated by shunting or not shunting the output monitoring current IOM (the multiple system monitoring currents ISM). The overcurrent protection circuit 17 indirectly monitors the output current IO via the output monitoring current IOM.

The overcurrent protection circuit 17 can also be configured to generate an overcurrent detection signal SOD when the output monitoring current IOM exceeds a predetermined threshold, and output the overcurrent detection signal SOD to the gate control circuit 15. The overcurrent detection signal SOD is a signal for limiting (for example, disconnecting) a portion or all of the n gate signals G generated in the gate control circuit 15 to be less than a predetermined value. In response to the overcurrent detection signal SOD, the gate control circuit 15 limits a portion or all of the n gate signals G to suppress an overcurrent flowing through the main transistor 8. When the output monitoring current IOM becomes less than the predetermined threshold, the overcurrent protection circuit 17 stops generating the overcurrent detection signal SOD, so that gate control circuit 15 (the main transistor 8) transitions to normal control.

The configuration (operation) of the overcurrent protection circuit 17 above is merely an example. The overcurrent protection circuit 17 can have various current/voltage characteristics and various operation modes. The overcurrent protection circuit 17 can have a circuit configuration which includes at least one current/voltage characteristic of constant current/voltage droop characteristics, foldback current limiting characteristics and constant power control voltage droop characteristics. The overcurrent protection circuit 17 can also have a circuit configuration including an automatic recovery type or a latch type (an off type without automatic recovery) operation mode.

Referring to FIG. 2, the semiconductor device 1 further includes an interlayer insulating layer 19 covering the first main surface 3. The interlayer insulating layer 19 universally covers the first device region 6 and the second device region 7. In this embodiment, the interlayer insulating layer 19 includes a multi-layer wiring structure having a laminated structure formed by alternately laminating multiple insulating layers and multiple wiring layers. Each of the insulating layers includes at least one of a silicon oxide (SiO) film and a silicon nitride (SiN) film. Each of the wiring layers can include at least one of a pure aluminum (Al) layer (an Al layer having a purity of 99% or more), a copper (Cu) layer (a Cu layer having a purity of 99% or more), an AlCu alloy layer, an AlSiCu alloy layer and an AlSi alloy layer.

Referring to FIG. 2 to FIG. 6, the semiconductor device 1 further includes n main gate wirings 20 as an example of control wirings disposed on anywhere above the first main surface 3. The n main gate wirings 20 include n wiring layers selectively routed into the interlayer insulating layer 19. The n main gate wirings 20 are electrically connected to the n first gates FG of the main transistor 8 in one-to-one correspondence to be electrically independent from one another in the first device region 6. The n main gate wirings 20 are individually electrically connected to the control IC 14 (the gate control circuit 15) in the second device region 7. The n main gate wirings 20 individually transmit the n gate signals G generated by the control IC 14 (the gate control circuit 15) to the n first gates FG of the main transistor 8.

The n main gate wirings 20 are respectively electrically connected to the third gates TG of the one or multiple unit transistors 10 to be systemized from the collection including the multiple unit transistors 10 as individual control targets. The n main gate wirings 20 can include one or multiple main gate wirings 20 electrically connected to one unit transistor 10 to be systemized as an individual control target. Moreover, the n main gate wirings 20 can also include one or multiple main gate wirings 20 connected in parallel with multiple unit transistors 10 to be systemized as individual control targets.

The semiconductor device 1 further includes n monitoring gate wirings 21 as an example of monitoring control wirings disposed on anywhere above the first main surface 3. The n monitoring gate wirings 21 include n wiring layers selectively routed into the interlayer insulating layer 19. The n monitoring gate wirings 21 are electrically connected to the n first monitoring gates FMG of the monitoring transistor 11 in one-to-one correspondence to be electrically independent from one another in the first device region 6. The n monitoring gate wirings 21 are individually electrically connected to the control IC 14 (the gate control circuit 15) in the second device region 7. The n monitoring gate wirings 21 individually transmit the n monitoring gate signals MG generated by the control IC 14 (the gate control circuit 15) to the n first monitoring gates FMG of the monitoring transistor 11.

The n monitoring gate wirings 21 are respectively electrically connected to the third monitoring gates TMG of the one or multiple unit monitoring transistors 13 to be systemized from the collection including the multiple unit monitoring transistors 13 as individual control targets. The n monitoring gate wirings 21 can include one or multiple monitoring gate wirings 21 electrically connected to one unit monitoring transistor 13 to be systemized as an individual control target. Moreover, the n monitoring gate wirings 21 can also include one or multiple monitoring gate wirings 21 connected in parallel with multiple unit monitoring transistors 13 to be systemized as individual control targets.

In this embodiment, the n monitoring gate wirings 21 are electrically connected to the corresponding main gate wirings 20 in one-to-one correspondence, respectively. The n monitoring gate wirings 21 can also be formed integrally with the corresponding main gate wirings 20, respectively. The n monitoring gate wirings 21 are individually electrically connected to the control IC 14 (the gate control circuit 15) via the corresponding main gate wirings 20, respectively. The n monitoring gate wirings 21 individually transmit the n gate signals G (the n monitoring gate signals MG) generated by the control IC 14 (the gate control circuit 15) to the n first monitoring gates FMG of the monitoring transistor 11.

Referring to FIG. 1 and FIG. 2, the semiconductor device 1 further includes multiple terminal electrodes 22 to 27. In FIG. 1, the multiple terminal electrodes 22 to 27 are indicated by shading lines. The number, configuration and planar shape of the multiple terminal electrodes 22 to 27 can be adjusted to any forms according to specifications of the main transistor 8 or specifications of the control IC 14, and are not limited to the forms shown in FIG. 1 and FIG. 2. In this embodiment, the multiple terminal electrodes 22 to 27 include a drain terminal 22 (a power supply terminal VBB), a source terminal 23 (an output terminal OUT), an input terminal 24, a ground terminal 25, an enable terminal 26 and a sensing terminal 27.

The drain terminal 22 is electrically connected to the first drain FD of the main transistor 8, the first monitoring drain FMD of the monitoring transistor 11 and the control IC 14. The drain terminal 22 transmits the power supply voltage VBB to various circuits such as the first drain FD of the main transistor 8, the first monitoring drain FMD of the monitoring transistor 11 and the control IC 14. The source terminal 23 is electrically connected to the first source FS of the main transistor 8 and the control IC 14. The source terminal 23 transmits the output current IO generated by the main transistor 8 to the outside.

The input terminal 24 transmits an input voltage that drives the control IC 14. The ground terminal 25 transmits a ground voltage GND. The enable terminal 26 transmits an electrical signal that enables or disables a portion or all of the functions of the control IC 14. The sensing terminal 27 transmits an electrical signal for detecting anomalies of the main transistor 8, the monitoring transistor 11 and the control IC 14.

The drain terminal 22 directly covers the second main surface 4 of the semiconductor chip 2, and is electrically connected to the second main surface 4. The drain terminal 22 can include at least one of a Ti layer, Ni layer, Au layer, Ag layer and Al layer. The drain terminal 22 can be a laminated structure obtained by laminating at least two of a Ti layer, Ni layer, Au layer, Ag layer and Al layer in any form.

The source terminal 23, the input terminal 24, the ground terminal 25, the enable terminal 26 and the sensing terminal 27 are disposed above the interlayer insulating layer 19. The source terminal 23 is formed above the first device region 6 in the first main surface 3. The input terminal 24, the ground terminal 25, the enable terminal 26 and the sensing terminal 27 are individually disposed above a region (more specifically, the second device region 7) outside the first device region 6 in the first main surface 3. The terminal electrodes 23 to 27 can include at least one of a pure Al layer, a pure Cu layer, an AlCu alloy layer, an AlSiCu alloy layer and an AlSi alloy layer. A plating layer can be formed on an outer surface of each of the terminal electrodes 23 to 27. The plating layer can include at least one of a Ni layer, a Pd layer and an Au layer.

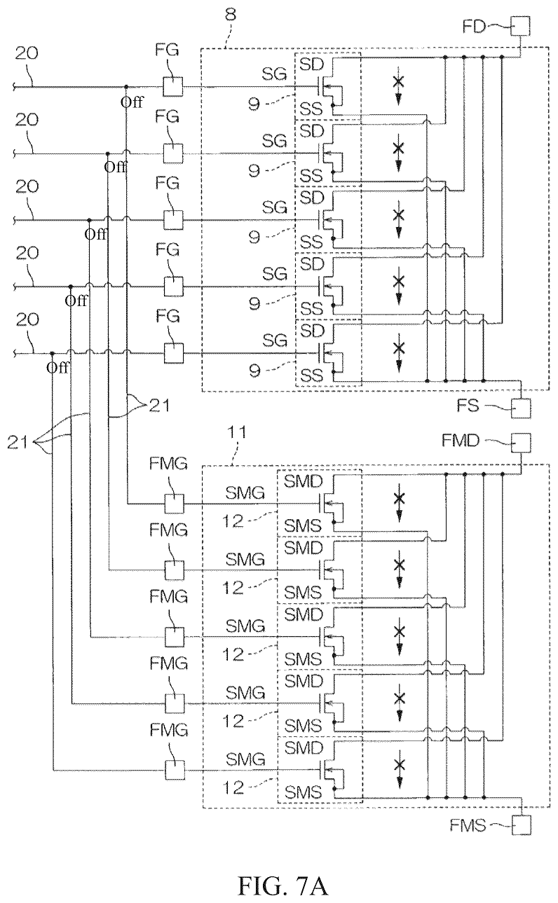

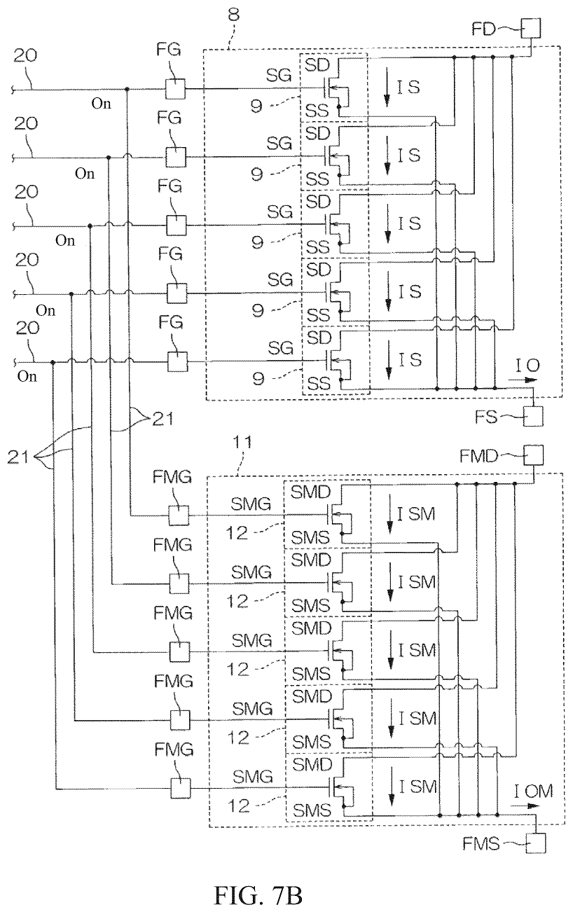

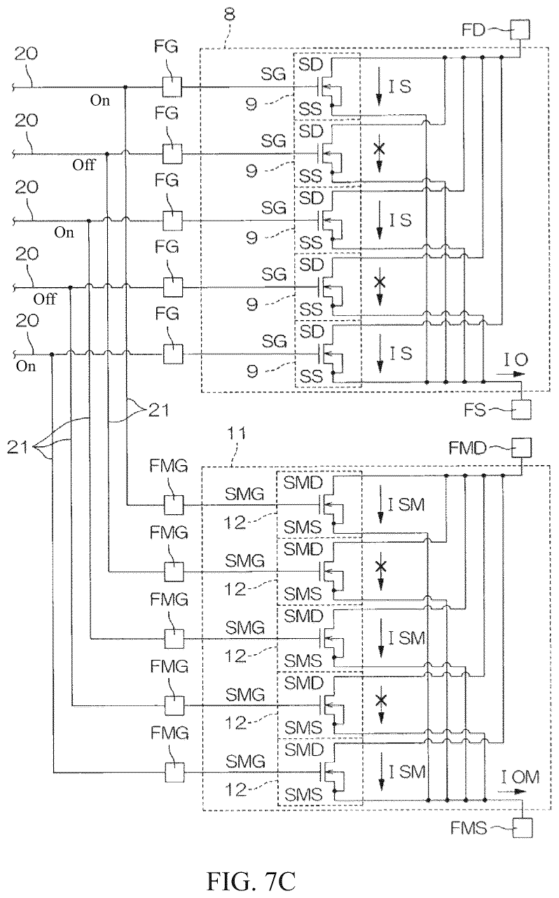

FIG. 7A to FIG. 7C respectively correspond to FIG. 5, and are circuit diagrams for illustrating operation examples of the main transistor 8 and the monitoring transistor 11. Referring to FIG. 7A, the gate signals G less than the gate threshold voltage (that is, off signals) are input to all of the n main gate wirings 20. The control above is used during an off operation of the main transistor 8. Thus, in the main transistor 8, all of the system transistors 9 are turned off, and accordingly the main transistor 8 is turned off. In the monitoring transistor 11, the n system monitoring transistors 12 and the n system transistors 9 in conjunction are turned off. Accordingly, the monitoring transistor 11 is turned off in conjunction with the main transistor 8.

Referring to FIG. 7B, the gate signals G greater than the gate threshold voltage (that is, on signals) are input to all of the n main gate wirings 20. The control above is used during a normal operation of the main transistor 8. Accordingly, the n system transistors 9 are turned on, and thus the main transistor 8 is turned on. The main transistor 8 generates the output current IO including the n system currents IS generated by the n system transistors 9. In this case, the channel utilization rate of the main transistor 8 is improved and the on resistance is reduced.

In the monitoring transistor 11, the n system monitoring transistors 12 and the n system transistors 9 in conjunction are turned on. Accordingly, the monitoring transistor 11 is turned on in conjunction with the main transistor 8. The monitoring transistor 11 generates the output monitoring current IOM including the n system monitoring currents ISM generated by the n system monitoring transistors 12, and monitors the output current IO. In this case, the channel utilization rate of the monitoring transistor 11 is improved and the on resistance is reduced.

Referring to FIG. 7C, the gate signals G greater than the gate threshold voltage (that is, on signals) are input to x (1≤x<n) main gate wirings 20, and the gate signals G less than the gate threshold voltage (that is, off signals) are input to (n-x) main gate wirings 20. The control above is used during an active clamping operation of the main transistor 8. Accordingly, x system transistors 9 are turned on, (n-x) system transistors 9 are turned off, and accordingly the main transistor 8 is turned on in a state where a current path of a portion thereof is conducted and a current path of a portion thereof is disconnected.

The main transistor 8 generates the output current IO including x system currents IS generated by the x system transistors 9. In other words, the main transistor 8 generates the above output current IO, which includes x system currents IS having absolute values more than 0 V and (n-x) system currents IS in 0 A. In this case, the channel utilization rate of the main transistor 8 is reduced and the on resistance is increased.

In the monitoring transistor 11, the x system monitoring transistors 12 are turned on in conjunction with the x system transistors 9, and the (n-x) system monitoring transistors 12 are turned off in conjunction with the (n-x) system transistors 9. Accordingly, in conjunction with the main transistor 8, the monitoring transistor 11 is turned on in a state where a current path of a portion thereof is conducted and a current path of a portion thereof is disconnected.

The monitoring transistor 11 generates the output monitoring current IOM including the x system monitoring currents ISM generated by the x system monitoring transistors 12, and monitors the output current IO. In other words, the monitoring transistor 11 generates the above output monitoring current IOM, which includes x system monitoring currents ISM having absolute values more than 0 V and (n-x) system monitoring currents ISM in 0 A. In this case, the channel utilization rate of the monitoring transistor 11 is reduced and the on resistance is increased.

In FIG. 7A to FIG. 7C, a portion or all (all in this embodiment) of the output monitoring current IOM generated by the monitoring transistor 11 is input to the overcurrent protection circuit 17 (referring to FIG. 4). When the output monitoring current IOM exceeds the predetermined threshold, the overcurrent protection circuit 17 generates the overcurrent detection signal SOD, and outputs the overcurrent detection signal SOD to the gate control circuit 15. In response to the overcurrent detection signal SOD, the gate control circuit 15 limits a portion or all of the n gate signals G, and limits a portion or all of the n system currents IS generated by the n system transistors 9. When the output monitoring current IOM becomes less than the predetermined threshold, the overcurrent protection circuit 17 stops generating the overcurrent detection signal SOD, so that gate control circuit 15 (the main transistor 8) transitions to normal control.

As such, in the semiconductor device 1, the main transistor 8 of the n systems is configured to have an on resistance (a channel utilization rate) that changes by individual control on the n system transistors 9. Specifically, the main transistor 8 is controlled by individual control of the n system transistors 9 so that the on resistance during the active clamping operation is different from the on resistance during the normal operation. More specifically, the main transistor 8 is controlled by individual control of the n system transistors 9 so that the on resistance during the active clamping operation exceeds the on resistance during the normal operation.

On the other hand, the monitoring transistor 11 is configured to have an on resistance (a channel utilization rate) that changes by individual control on the m (m=n in this embodiment) system monitoring transistors 12. More specifically, the monitoring transistor 11 is configured to have an on resistance that changes in conjunction with the main transistor 8. Specifically, in conjunction with the main transistor 8, the monitoring transistor 11 is controlled so that the on resistance during the active clamping operation is different from the on resistance during the normal operation. More specifically, in conjunction with the main transistor 8, the monitoring transistor 11 is controlled so that the on resistance during the active clamping operation exceeds the on resistance during the normal operation.

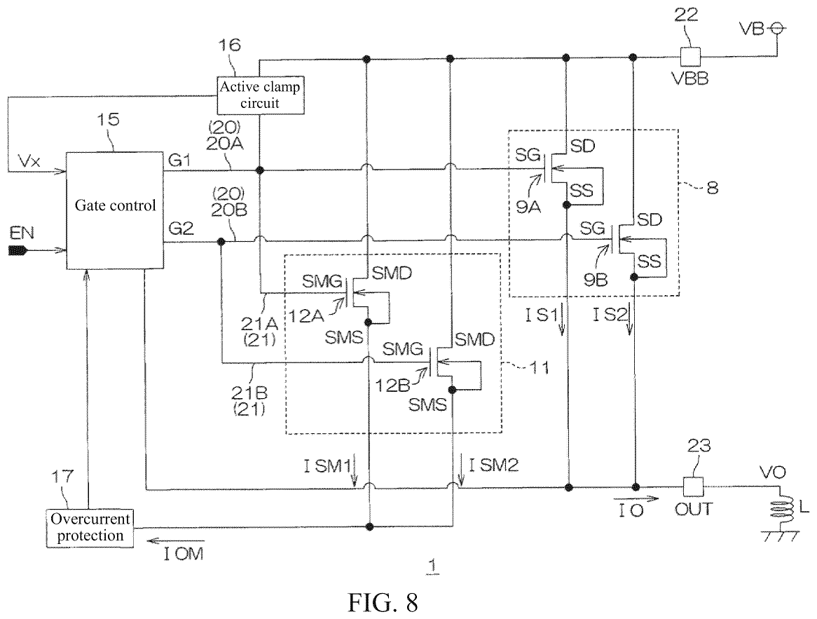

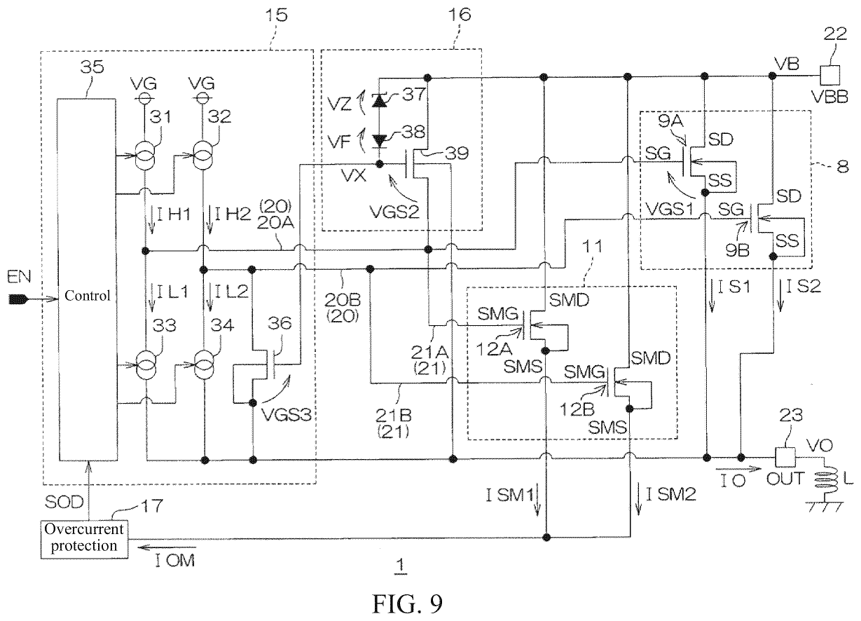

FIG. 8 shows a circuit block diagram of a configuration example of an electrical structure of the semiconductor device 1 in FIG. 1 (equivalent to a configuration example applying the main transistor 8 of two systems and the monitoring transistor 11 of two systems). FIG. 9 shows a circuit diagram of a configuration example of the circuit block diagram in FIG. 8. FIG. 8 and FIG. 9 are also circuit diagrams showing a main portion of the control IC 14. FIG. 8 and FIG. 9 depict an example in which the inductive load L is connected to the source terminal 23.

The semiconductor device 1 includes the main transistor 8 of two systems (n=2), the monitoring transistor 11 of two systems (m=n=2), two (n=2) main gate wirings 20, two (m=n=2) monitoring gate wirings 21, the gate control circuit 15, the active clamp circuit 16 and the overcurrent protection circuit 17.

The main transistor 8 of two systems includes a first system transistor 9A and a second system transistor 9B. Two second gates SG form two first gates FG. Two second drains SD are individually electrically connected to the drain terminal 22. Two second sources SS are individually electrically connected to the source terminal 23.

The first system transistor 9A generates a first system current IS1, and the second system transistor 9B generates a second system current IS2. The main transistor 8 of two systems generates an output current IO including the first system current IS1 and the second system current IS2. It can be determined according to the description, the second system current IS2 can be different from the first system current IS1 or can be equal to the first system current IS1. In the description below, the first system current IS1 and the second system current IS2 are not specifically differentiated and are simply stated as the system current IS.

The main transistor 8 of two systems performs control in a first operation mode, a second operation mode and a third operation mode. In the first operation mode, both of the first and second system transistors 9A and 9B are controlled to be off. In the second operation mode, both of the first and second system transistors 9A and 9B are controlled to be on. In the third operation mode, only either of the first and second system transistors 9A and 9B is controlled to be on. In the third operation mode, in this embodiment, the first system transistor 9A is controlled to be on, while the second system transistor 9B is controlled to be off.

The monitoring transistor 11 of two systems includes a first system monitoring transistor 12A and a second system monitoring transistor 12B. Two second monitoring gates SMG form two first monitoring gates FMG. Two second monitoring drains SMD are individually electrically connected to the drain terminal 22. Two second monitoring sources SMS are electrically isolated from the source terminal 23 (the second sources SS of the first and second system transistors 9A and 9B).

The first system monitoring transistor 12A generates a first system monitoring current ISM1, and a second system monitoring transistor 12B generates a second system monitoring current ISM2. The monitoring transistor 11 of two systems generates an output monitoring current IOM including the first system monitoring current ISM1 and the second system monitoring current ISM2. It can be determined according to the description, the second system monitoring current ISM2 can be different from the first system monitoring current ISM1 or can be equal to the first system monitoring current ISM1. In the description below, the first system monitoring current ISM1 and the second system monitoring current ISM2 are not specifically differentiated and are simply stated as the system monitoring current ISM.

The monitoring transistor 11 of two systems performs control in a first operation mode, a second operation mode and a third operation mode. In the first operation mode, both of the first and second system monitoring transistors 12A and 12B are controlled to be off. In the second operation mode, both of the first and second system monitoring transistors 12A and 12B are controlled to be on. In the third operation mode, only either of the first and second system monitoring transistors 12A and 12B is controlled to be on. In the third operation mode, in this embodiment, the first system monitoring transistor 12A is controlled to be on, while the second system monitoring transistor 12B is controlled to be off. In this embodiment, the first to third operation modes of the monitoring transistor 11 are performed in conjunction with the first to third operation modes of the main transistor 8.

The two main gate wirings 20 include a first main gate wiring 20A and a second main gate wiring 20B. The first main gate wiring 20A is electrically connected to the second gate SG of the first system transistor 9A. The second main gate wiring 20B is electrically connected to the second gate SG of the second system transistor 9B.

The two monitoring gate wirings 21 include a first monitoring gate wiring 21A and a second monitoring gate wiring 21B. The first monitoring gate wiring 21A is electrically connected to the first main gate wiring 20A and the second monitoring gate SMG of the first system monitoring transistor 12A. The second monitoring gate wiring 21B is electrically connected to the second main gate wiring 20B and the second monitoring gate SMG of the second system monitoring transistor 12B.

In the description below, “a state of being electrically connected to the first main gate wiring 20A” includes “a state of being electrically connected to the second gate SG of the first system transistor 9A” and “a state of being electrically connected to the second monitoring gate SMG of the first system monitoring transistor 12A”. Moreover, “a state of being electrically connected to the second main gate wiring 20B” includes “a state of being electrically connected to the second gate SG of the second system transistor 9B” and “a state of being electrically connected to the second monitoring gate SMG of the second system monitoring transistor 12B”.

The gate control circuit 15 is electrically connected to the first and second main gate wirings 20A and 20B. In response to an enable signal EN, the gate control circuit 15 generates first and second gate signals G1 and G2, and outputs the first and second gate signals G1 and G2 to the first and second main gate wirings 20A and 20B, respectively. First and second monitoring gate signals MG1 and MG2 input to the first and second system monitoring transistors 12A and 12B include the first and second gate signals G1 and G2, respectively.

More specifically, in an enabled state when the enable signal EN is at a high level (EN=H), the gate control circuit 15 generates the first and second gate signals G1 and G2 that control both of the first and second system transistors 9A and 9B and both of the first and second system monitoring transistors 12A and 12B to be on. In a disabled state when the enable signal EN is at a low level (EN=L), the gate control circuit 15 generates the first and second gate signals G1 and G2 that control both of the first and second system transistors 9A and 9B and both of the first and second system monitoring transistors 12A and 12B to be off.

In this embodiment, the gate control circuit 15 includes a first current source 31, a second current source 32, a third current source 33, a fourth current source 34, a controller 35 and an n-channel drive MISFET 36. Although omitted from the drawings, the first current source 31, the second current source 32, the third current source 33, the fourth current source 34, the controller 35 and the drive MISFET 36 are individually formed in the second device region 7.

The first current source 31 generates a first source current IH1. The first current source 31 is electrically connected to an application end of a boost voltage VG (equivalent to a charge pump output) and the first main gate wiring 20A. The second current source 32 generates a second source current IH2. The second current source 32 is electrically connected to the application end of the boost voltage VG and the second main gate wiring 20B. The third current source 33 generates a first sink current IL1. The third current source 33 is electrically connected to the first main gate wiring 20A and the source terminal 23. The fourth current source 34 generates a second sink current IL2. The fourth current source 34 is electrically connected to the second main gate wiring 20B and the source terminal 23.

The controller 35 is electrically connected to the first to fourth current sources 31 to 34. In an enabled state (EN=H), the controller 35 controls the first and second current sources 31 and 32 to be on, while controlling the third and fourth current sources 33 to 34 to be off. Thus, the first source current IH1 is output to the first main gate wiring 20A, and the second source current IH2 is output to the second main gate wiring 20B. In a disabled state (EN-L), the controller 35 controls the first and second current sources 31 and 32 to be off, while controlling the third and fourth current sources 33 to 34 to be on. Thus, the first sink current IL1 is sourced from the first main gate wiring 20A, and the second sink current IL2 is sourced from the second main gate wiring 20B.

The drive MISFET 36 is electrically connected to the second main gate wiring 20B and the source terminal 23. The driver MISFET 36 includes a drain, a source, a gate and a back gate. The drain of the drive MISFET 36 is electrically connected to the second main gate wiring 20B. The source of the drive MISFET 36 is electrically connected to the source terminal 23. The back gate of the drive MISFET 36 is electrically connected to the source terminal 23.

The active clamp circuit 16 is connected between the drain and the gate of the first system transistor 9A. Moreover, the active clamp circuit 16 is connected between the drain and the gate of the first system monitoring transistor 12A. The active clamp circuit 16 is configured to cooperate with the gate control circuit 15 to control both of the first system transistor 9A and the first system monitoring transistor 12A to be on, and to control both of the second system transistor 9B and the second system monitoring transistor 12B to be off, when the first source FS (the source terminal 23) of the main transistor 8 reaches a negative voltage.

More specifically, the active clamp circuit 16 has an internal node voltage Vx electrically connected to the gate control circuit 15. The active clamp circuit 16 controls the gate control circuit 15 via the internal node voltage Vx so as to generate the first and second gate signals G1 and G2, which control both of the first system transistor 9A and the first system monitoring transistor 12A to be on, while controlling both of the second system transistor 9B and the second system monitoring transistor 12B to be off

More specifically, after the enabled state (EN=H) transitions to the disabled state (EN=L) and before the main transistor 8 proceeds to the active clamping operation, the active clamp circuit 16 controls the gate control circuit 15 via the internal node voltage Vx so as to generate the first and second gate signals G1 and G2, which control both of the first system transistor 9A and the first system monitoring transistor 12A to be on, while controlling both of the second system transistor 9B and the second system monitoring transistor 12B to be off.

“Before the main transistor 8 proceeds to the active clamping operation” specifically refers to “before the output voltage VO is clamped”. Both of the second system transistor 9B and the second system monitoring transistor 12B are fixed at the output voltage VO via the second gate signal G2 and are controlled to be off. That is to say, a short circuit is generated between the gate and the source of the second system transistor 9B, and a short circuit is generated between the gate and the source of the second system monitoring transistor 12B.

The active clamp circuit 16 limits the drain-source voltage (=VBB-VOUT) of the main transistor 8 to be below a clamp voltage Vclp. In this embodiment, the second system transistor 9B and the second system monitoring transistor 12B do not contribute to the active clamping operation. Thus, the active clamp circuit 16 is not connected to the second system transistor 9B and the second system monitoring transistor 12B.

In this embodiment, the active clamp circuit 16 includes a Zener diode string 37, a diode string 38 and an n-channel clamp MISFET 39. Although omitted from the drawings, the Zener diode string 37, the diode string 38 and the clamp MISFET 39 are individually formed in the second device region 7.

The Zener diode string 37 includes a serial circuit including multiple (for example, eight) Zener diodes connected in series in a forward direction. The number of the Zener diodes can be any as desired, and can be one. The Zener diode string 37 includes a cathode and an anode. The cathode of the Zener diode string 37 is electrically connected to the drain terminal 22, and the second drains SD of the first and second system transistors 9A and 9B. The diode string 38 includes a serial circuit including multiple (for example, three) pn junction diodes connected in series in a forward direction. The number of the pn junction diodes can be any as desired, and can be one. The diode string 38 includes a cathode and an anode. The anode of the diode string 38 is bias connected in a reverse direction to the anode of the Zener diode string 37.

The clamp MISFET 39 includes a drain, a source, a gate and a back gate. The drain of the clamp MISFET 39 is electrically connected to the drain terminal 22, and the second drains SD of the first and second system transistors 9A and 9B. The source of the clamp MISFET 39 is electrically connected to the first main gate wiring 20A. The gate of the clamp MISFET 39 is electrically connected to the cathode of the diode string 38. The back gate of the clamp MISFET 39 is electrically connected to the source terminal 23.

The internal node voltage Vx of the active clamp circuit 16 is electrically connected to the gate of the drive MISFET 36. The active clamp circuit 16 controls the drive MISFET 36 to be on or off according to the internal node voltage Vx. The internal node voltage Vx can be any voltage in the active clamp circuit 16. The internal node voltage Vx can also be a gate voltage of the clamp MISFET 39, or can be an anode voltage of any pn junction diode in the diode string 38.

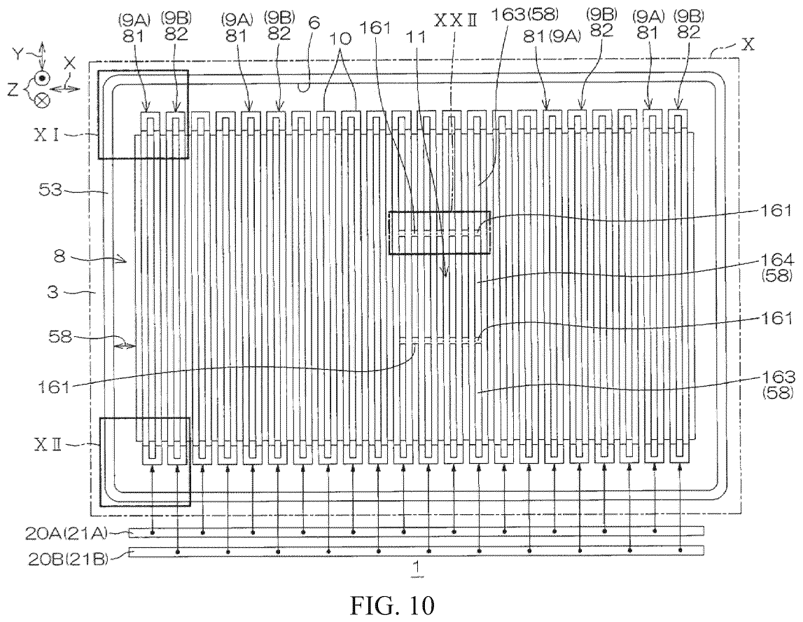

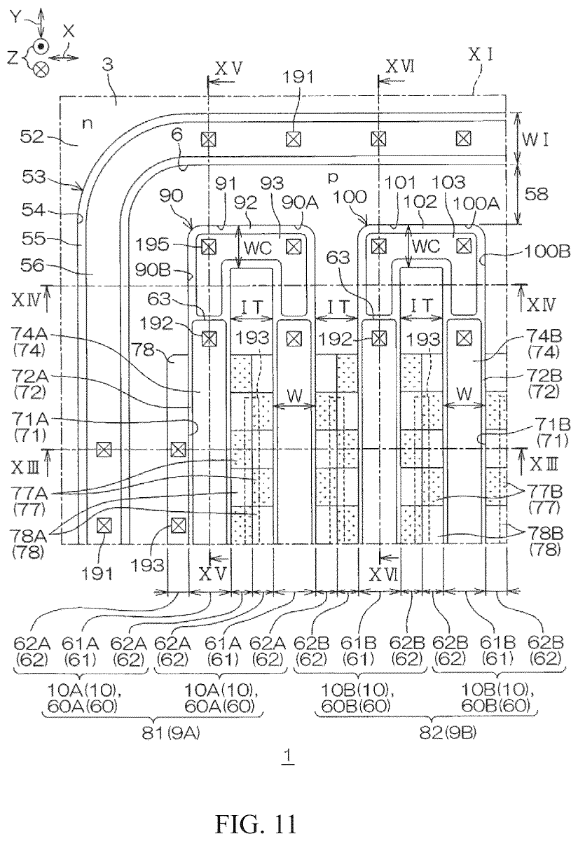

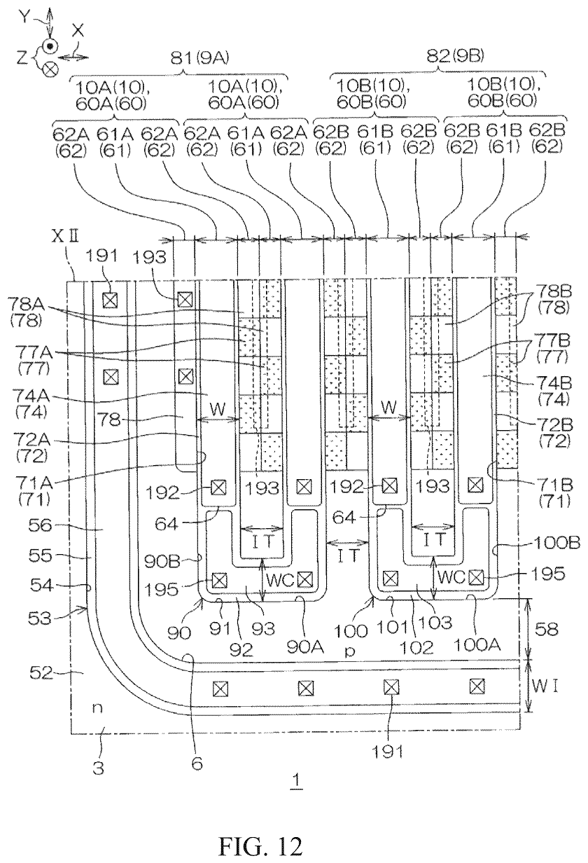

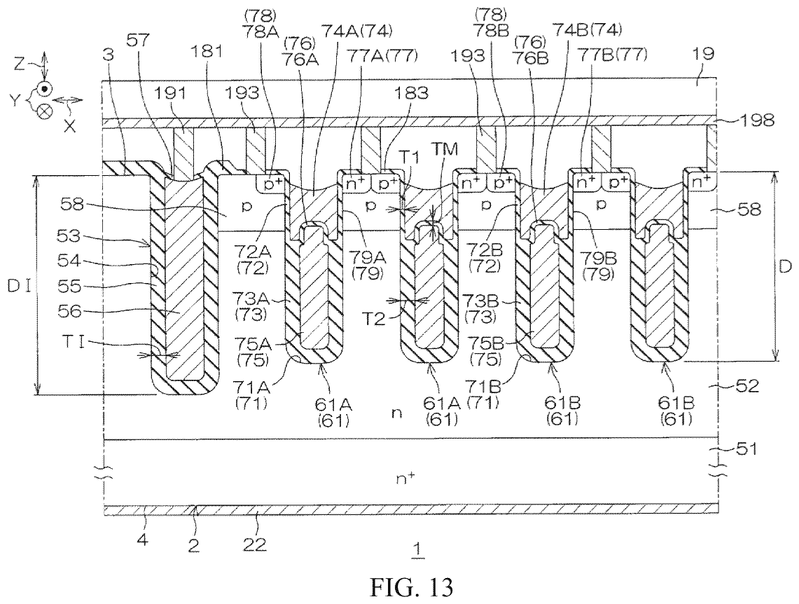

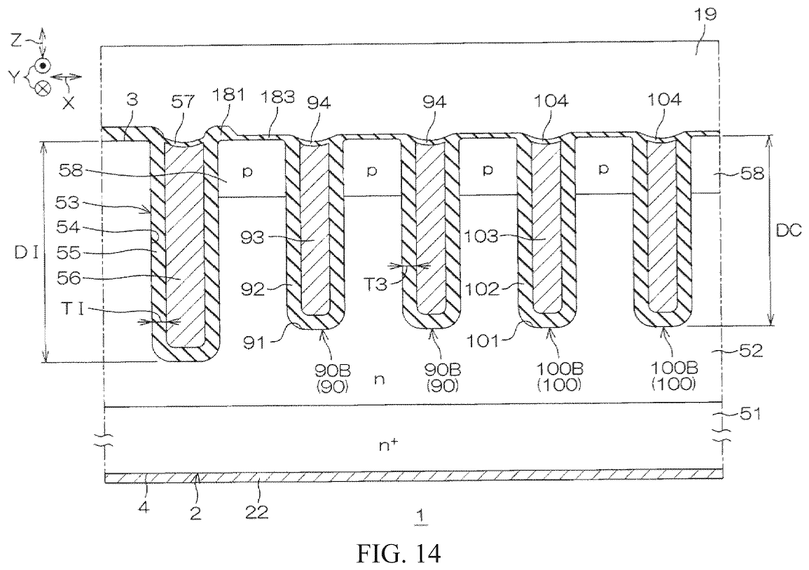

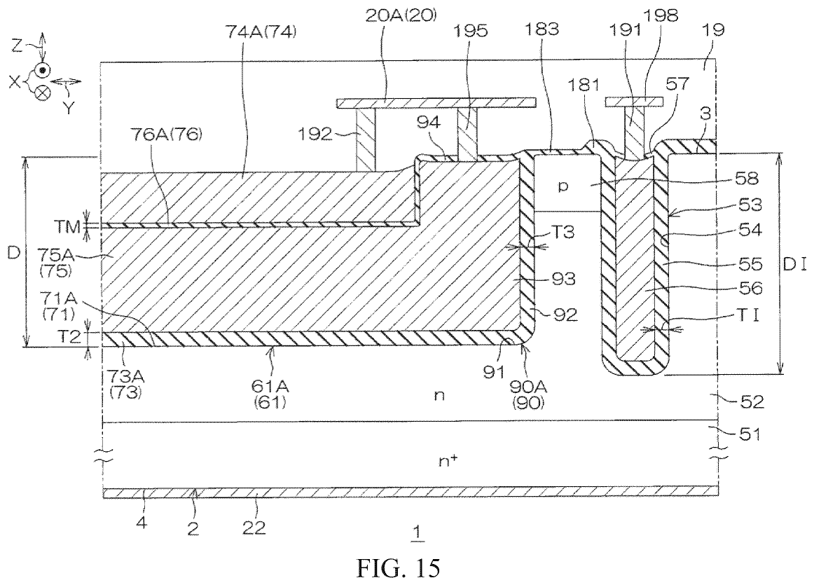

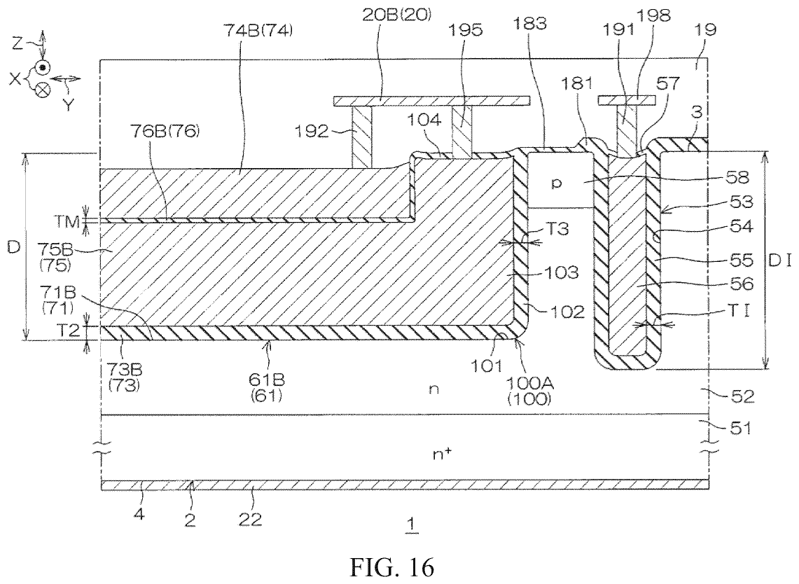

FIG. 10 shows an enlarged diagram of a region X shown in FIG. 3, and is a plan view of a layout example of the main transistor 8 and the monitoring transistor 11 in FIG. 8. FIG. 11 shows an enlarged diagram of a region XI shown in FIG. 10. FIG. 12 shows an enlarged diagram of a region XII shown in FIG. 10. FIG. 13 shows a cross-sectional view along a section line XIII-XIII in FIG. 11. FIG. 14 shows a cross-sectional view along a section line XIV-XIV in FIG. 11. FIG. 15 shows a cross-sectional view along a section line XV-XV in FIG. 11. FIG. 16 shows a cross-sectional view along a section line XVI-XVI in FIG. 11.

Referring to FIG. 10 to FIG. 16, the semiconductor device 1 further includes an n-type (a first conductivity type) first semiconductor region 51 formed in a surface layer of the second main surface 4 of the semiconductor chip 2. The first semiconductor region 51 forms the first drain FD of the main transistor 8 and the first monitoring drain FMD of the monitoring transistor 11. The first semiconductor region 51 can also be referred to as “a drain region”. The first semiconductor region 51 is formed in an entire region of the surface layer of the second main surface 4, and is exposed from the second main surface 4 and the first to fourth side surfaces 5A to 5D.

An n-type impurity concentration of the first semiconductor region 51 can be between about 1×10¹⁸ cm⁻³ and about 1×10²¹ cm⁻³. A thickness of the first semiconductor region 51 can be between about 10 μm and about 450 μm. The thickness of the first semiconductor region 51 is preferably between about 50 μm and about 150 μm. In this embodiment, the first semiconductor region 51 is formed by an n-type semiconductor substrate (Si substrate).

The semiconductor device 1 further includes an n-type second semiconductor region 52 formed in a surface layer of the first main surface 3 of the semiconductor chip 2. The second semiconductor region 52 and the first semiconductor region 51 together form the first drain FD of the main transistor 8 and the first monitoring drain FMD of the monitoring transistor 11. The second semiconductor region 52 can also be referred to as “a drift region”. The second semiconductor region 52 is formed in an entire region of the surface layer of the first main surface 3 to be electrically connected to first semiconductor region 51, and is exposed from the first main surface 3 and the first to fourth side surfaces 5A to 5D.

The second semiconductor region 52 has an n-type impurity concentration less than the n-type impurity concentration of the first semiconductor region 51. The n-type impurity concentration of the second semiconductor region 52 can be between about 1×10¹⁵ cm⁻³ and about 1×10¹⁸ cm⁻³. The second semiconductor region 52 has a thickness less than the thickness of the first semiconductor region 51. The thickness of the second semiconductor region 52 can be between about 1 μm and about 25 μm. The thickness of the second semiconductor region 52 is preferably between about 5 μm and about 15 μm. In this embodiment, the second semiconductor region 52 is formed by an n-type epitaxial layer (Si epitaxial layer).

The semiconductor device 1 further includes a trench separation structure 53 as an example of a region separation structure that defines the first device region 6 on the first main surface 3. The trench separation structure 53 can also be referred to as “a deep trench isolation (DTI) structure”. The trench separation structure 53 is formed to have a loop shape surrounding a partial region of the first main surface 3 in the plan view, and defines the first device region 6 in a predetermined shape.

In this embodiment, the trench separation structure 53 is formed to have a square loop shape with four sides parallel to the first to fourth side surfaces 5A to 5D in the plan view to define the first device region 6 having a quadrilateral shape. A planar shape of the trench separation structure 53 can be any as desired, and can also be formed to have a polygonal loop shape. The first device region 6 can also be defined to have a polygonal shape according to the planar shape of the trench separation structure 53.

The trench separation structure 53 has a separation width WI and a separation depth DI. The separation width WI is a width in a direction perpendicular to an extension direction of the trench separation structure 53 in the plan view. The separation width WI can be between about 0.5 μm and about 2.5 μm. The separation width WI is preferably between about 1.2 μm and about 2 μm. The separation depth DI can be between about 1 μm and about 10 μm. The separation depth DI is preferably between about 2 μm and about 6 μm.

A depth/width ratio DI/WI of the trench separation structure 53 can be between about 1 and about 5. The depth/width ratio DI/WI is a ratio of the separation depth DI to the separation width WI. The depth/width ratio DI/WI is preferably more than or equal to 2. A bottom wall of the trench separation structure 53 is preferably formed at an interval of between about 1 μm and about 5 μm from a bottom of the second semiconductor region 52.

The trench separation structure 53 has a corner connecting a portion extending along the first direction X and a portion extending along the second direction Y into an arc (curved) shape. In this embodiment, four corners of the trench separation structure 53 have an arc shape. That is to say, the first device region 6 is defined to have a quadrilateral shape having four corners respectively extending in an arc shape. The corners of the trench separation structure 53 preferably have a fixed separation width WI along an arc direction.

The trench separation structure 53 has a single-electrode structure, and includes a separation trench 54, a separation insulating film 55 (a separation insulator), an isolation electrode 56 and a separation cap insulating film 57. The separation trench 54 is etched from the first main surface 3 toward the second main surface 4. The separation trench 54 is formed at an interval from a bottom of the second semiconductor region 52 toward the side of the first main surface 3.

The separation trench 54 includes a sidewall and a bottom wall. An angle formed between the sidewall of the separation trench 54 and the first main surface 3 in the semiconductor chip 2 can be between about 90° and about 92°. The separation trench 54 can be formed to have a front end tapered shape with an opening width that narrows from an opening toward the bottom wall. Corners of the bottom wall of the separation trench 54 are preferably formed to have a curved shape. The entire bottom wall of the separation trench 54 can be formed to have a curved shape facing the second main surface 4.

The separation insulating film 55 is formed on a wall surface of the separation trench 54. More specifically, the separation insulating film 55 is formed film-like in an entire region of the wall surface of the separation trench 54, and defines a recessed space in the separation trench 54. The separation insulating film 55 preferably includes a silicon oxide film. The separation insulating film 55 in particular preferably includes a silicon oxide film formed by an oxide of the semiconductor chip 2.

The separation insulating film 55 has a separation thickness TI. The separation thickness TI is a thickness along a normal direction of the wall surface of the separation trench 54. The separation thickness TI can be between about 0.1 μm and about 1 μm. The separation thickness TI is preferably between about 0.15 μm and about 0.65 μm. The thickness of a portion of the separation insulating film 55 covering the bottom wall of the separation trench 54 can be less than the thickness of a portion covering the sidewall of the separation trench 54.

The isolation electrode 56 is buried in the separation trench 54 in a manner of separation by the separation insulating film 55 as an integrated member. In this embodiment, the isolation electrode 56 includes a conductive polycrystalline silicon. A source potential is applied to the isolation electrode 56. The isolation electrode 56 has an electrode surface (an isolation electrode surface) exposed from the separation trench 54. The electrode surface of the isolation electrode 56 can be recessed toward the bottom wall of the separation trench 54 to form a curved shape. The electrode surface of the isolation electrode 56 is preferably separated from the first main surface 3 toward the bottom wall of the separation trench 54 by an interval of between about 0 Å and about 200 Å in a depth direction of the separation trench 54. The electrode surface of the isolation electrode 56 is in particular preferably separated from the first main surface 3 toward the bottom wall of the separation trench 54 by an interval of less than 1000 Å.

Moreover, in FIG. 13 to FIG. 16, the entire electrode surface of the isolation electrode 56 is closer to the bottom than the first main surface 3, but the electrode surface of the isolation electrode 56 can also have a portion closer to the top than the first main surface 3. For example, the isolation electrode 56 can have a protruding portion extending to closer to the top than the first main surface 3, and has the recessed and curved electrode surface at the protruding portion.

The separation cap insulating film 57 as a film covers the electrode surface of the isolation electrode 56 in the separation trench 54. The separation cap insulating film 57 suppresses short-circuitry of the isolation electrode 56 with other electrodes. The separation cap insulating film 57 is connected to the separation insulating film 55. The separation cap insulating film 57 preferably includes a silicon oxide film. The separation cap insulating film 57 in particular preferably includes a silicon oxide film formed by an oxide of the isolation electrode 56. That is to say, preferably, the separation cap insulating film 57 includes a polysilicon oxide, and the separation insulating film 55 includes a monosilicon oxide.

The semiconductor device 1 further includes a p-type (a second conductivity type) body region 58 formed in the surface layer of the first main surface 3 in the first device region 6. A p-type impurity concentration of the body region 58 can be between about 1×10¹⁶ cm⁻³ and about 1×10¹⁸ cm⁻³. The body region 58 is formed in an entire region of the surface layer of the first main surface 3 in the first device region 6, and is in contact with the sidewall of the trench separation structure 53. The body region 58 is formed in a region on the side of the first main surface 3 with respect to the bottom wall of the trench separation structure 53. The body region 58 is preferably formed in a region on the side of the first main surface 3 with respect to a middle portion of the trench separation structure 53.

The semiconductor device 1 includes the main transistor 8 of two systems (n=2) formed in the first main surface 3 in the first device region 6. The main transistor 8 is formed in the first main surface 3 to be separated from the trench separation structure 53 in the plan view. The main transistor 8 includes multiple unit transistors 10 collectively formed in the first main surface 3 in the first device region 6.

The number of the unit transistors 10 can be any as desired. In FIG. 10, an example in which 44 unit transistors 10 are formed is depicted. The number of the unit transistors 10 is preferably even. The multiple unit transistors 10 are arranged in one row along the first direction X in the plan view, and each form a strip shape extending along the second direction Y. The multiple unit transistors 10 form strip shapes extending along the second direction Y in the plan view.

More specifically, each of the multiple unit transistors 10 includes a unit element 60. Each of the unit elements 60 includes one trench structure 61, and a channel element 62 controlled by the trench structure 61. The trench structure 61 can also be referred to as “a gate structure” or “a trench gate structure”. Each of the trench structures 61 forms the third gate TG of each of the unit transistors 10. The channel element 62 is a region in which connection and disconnection of a current path are controlled by the trench structure 61. In this embodiment, the unit element 60 includes a pair of channel elements 62 formed on both sides of one trench structure 61.

The multiple trench structures 61 in the plan view are arranged at intervals along the first direction X, and each form a strip shape extending along the second direction Y. That is to say, the multiple trench structures 61 form strip shapes extending along the second direction Y in the plan view. Each of the multiple trench structures 61 has a first end 63 on one side of the lengthwise direction (the second direction Y) and a second end 64 on the other side.

Each of the trench structures 61 has a trench width W and a trench depth D. The trench width W is a width in a direction (the first direction X) perpendicular to an extension direction of the trench structures 61. The trench width W is preferably less than the separation width WI of the trench separation structure 53 (W<WI). The trench width W can be between about 0.5 μm and about 2 μm. The trench width W is preferably between about 0.5 μm and about 1.5 μm. As a matter of course, the trench width W can also be substantially equivalent to the separation width WI (W [symbol] WI).

The trench depth D is preferably less than the separation depth DI of the trench separation structure 53 (D<DI). The trench depth D can be between about 1 μm and about 10 μm. The trench depth D is preferably between about 2 μm and about 6 μm. As a matter of course, the trench depth D can also be substantially equivalent to the separation depth DI (D [symbol] DI). A depth/width ratio D/W of the trench structure 61 can be between about 1 and about 5. The depth/width ratio D/W is a ratio of the trench depth D to the trench width W. The depth/width ratio D/W is preferably more than or equal to 2. A bottom wall of the trench structure 61 is preferably formed at an interval of between about 1 μm and about 5 μm from the bottom of the second semiconductor region 52.

The multiple trench structures 61 are arranged at a trench interval IT along the first direction X. The trench interval IT is preferably set as a value such that a depletion layer extending from the multiple trench structures 61 is integrated closer to the bottom than the bottom walls of the multiple trench structures 61. The trench interval IT can be between about 0.25 times and 1.5 times the trench width W. The trench interval IT is preferably less than or equal to the trench width W (IT≤W). The trench interval IT can be between about 0.5 μm and about 2 μm.

A configuration of one trench structure 61 is described below. The trench structure 61 has a multi-electrode structure, and includes a trench 71, an upper insulating film 72, a lower insulating film 73, an upper electrode 74, a lower electrode 75 and an intermediate insulating film 76. The trench 71 can also be referred to as “a gate trench”. The trench structure 61 includes a buried electrode (a gate electrode) buried in the trench 71 and separated by a buried insulator. The buried insulator includes the upper insulating film 72, the lower insulating film 73 and the intermediate insulating film 76. The buried electrode includes the upper electrode 74 and the lower electrode 75.

The trench 71 is etched from the first main surface 3 toward the second main surface 4. The trench 71 penetrates the body region 58, and is formed at an interval from the bottom of the second semiconductor region 52 toward the side of the first main surface 3. The trench 71 includes a sidewall and a bottom wall. An angle formed between the sidewall of the trench 71 and the first main surface 3 in the semiconductor chip 2 can be between about 90° and about 92°. The trench 71 can also be formed to have a front end tapered shape with an opening width that narrows from an opening toward the bottom wall. Corners of the bottom wall of the trench 71 are preferably formed to have a curved shape. The entire bottom wall of the trench 71 can be also formed to have a curved shape facing the second main surface 4.

The upper insulating film 72 covers an upper wall surface of the trench 71. More specifically, the upper insulating film 72 covers the upper wall surface in a region on the side of an opening of the trench 71 with respect to the bottom of the body region 58. The upper insulating film 72 crosses a boundary between the second semiconductor region 52 and the body region 58. The upper insulating film 72 has a portion covering the body region 58, and a portion covering the second semiconductor region 52. A covered area of the body region 58 by the upper insulating film 72 is greater than a covered area of the second semiconductor region 52 by the upper insulating film 72. The upper insulating film 72 preferably includes a silicon oxide film. The upper insulating film 72 in particular preferably includes a silicon oxide film formed by an oxide of the semiconductor chip 2. The upper insulating film 72 is formed as a gate insulating film.

The upper insulating film 72 has a first thickness T1. The first thickness T1 is a thickness along a normal direction of the wall surface of the trench 71. The first thickness T1 is less than the separation thickness TI of the separation insulating film 55 (T1<TI). The first thickness T1 can be between about 0.01 μm and about 0.05 μm. The first thickness T1 is preferably between about 0.02 μm and about 0.04 μm.

The lower insulating film 73 covers a lower wall surface of the trench 71. More specifically, the lower insulating film 73 covers the lower wall surface in a region on the side of the bottom wall of the trench 71 with respect to the bottom of the body region 58. The lower insulating film 73 defines a recessed space in a region on the side of the bottom wall of the trench 71. The lower insulating film 73 is in contact with the second semiconductor region 52. The lower insulating film 73 preferably includes a silicon oxide film. The lower insulating film 73 in particular preferably includes a silicon oxide film formed by an oxide of the semiconductor chip 2.

The lower insulating film 73 has a second thickness T2. The second thickness T2 is a thickness along the normal direction of the wall surface of the trench 71. The second thickness T2 is greater than the first thickness T1 of the upper insulating film 72 (T1<T2). The second thickness T2 can be substantially equivalent to the separation thickness TI of the separation insulating film 55 (T2 [symbol] TI) The second thickness T2 can be between about 0.1 μm and about 1 μm. The second thickness T2 is preferably between about 0.15 μm and about 0.65 μm. The thickness of a portion of the lower insulating film 73 covering the bottom wall of the trench 71 can be less than the thickness of a portion covering the sidewall of the trench 71.

The upper electrode 74 is separated by the upper insulating film 72 and buried on an upper side (the side of the opening) of the trench 71. The upper electrode 74 is buried as a strip shape extending along the second direction Y in the plan view. The upper electrode 74 faces the body region 58 and the second semiconductor region 52 across the upper insulating film 72. A facing area of the upper electrode 74 with respect to the body region 58 is greater than a facing area of the upper electrode 74 with respect to the second semiconductor region 52. The upper electrode 74 includes a conductive polycrystalline silicon. The upper electrode 74 is formed as a gate electrode. The gate signal G is input to the upper electrode 74.

The upper electrode 74 has an electrode surface (a buried electrode surface) exposed from the trench 71. The electrode surface of the upper electrode 74 can be recessed toward the bottom wall of the trench 71 to form a curved shape. The electrode surface of the upper electrode 74 is preferably located closer to the side of the bottom wall of the trench 71 than a depth position of the electrode surface of the isolation electrode 56 in the depth direction of the trench 71. The electrode surface of the upper electrode 74 is preferably separated from the first main surface 3 toward the bottom wall of the trench 71 by an interval of more than or equal to 2000 Å in the depth direction of the trench 71. The electrode surface of the upper electrode 74 is in particular preferably separated from the first main surface 3 toward the bottom wall of the trench 71 by an interval of between about 2500 Å and about 4500 Å.

The lower electrode 75 is separated by the lower insulating film 73 and buried on a lower side (the side of the bottom wall) of the trench 71. The lower electrode 75 is buried as a strip shape extending along the second direction Y in the plan view. The lower electrode 75 has a thickness (a length) greater than a thickness (a length) of the upper electrode 74 in the depth direction of the trench 71. The lower electrode 75 faces the second semiconductor region 52 across the lower insulating film 73. The lower electrode 75 has an upper end protruded from the lower insulating film 73 toward the side of the first main surface 3. The upper end of the lower electrode 75 is engaged with a bottom of the upper electrode 74, and faces the upper insulating film 72 across the bottom of the upper electrode 74 along a horizontal direction of the first main surface 3.

The lower electrode 75 includes a conductive polycrystalline silicon. In this embodiment, the lower electrode 75 is formed as a gate electrode. The lower electrode 75 is fixed at a potential same as the upper electrode 74. Moreover, the lower electrode 75 can also have a source potential. That is to say, the same gate signal G can be applied simultaneously to the upper electrode 74 and the lower electrode 75. Accordingly, a voltage drop between the upper electrode 74 and the lower electrode 75 can be suppressed, hence suppressing an electric field concentration between the upper electrode 74 and the lower electrode 75. Moreover, an on resistance of the semiconductor chip 2 (in particular the second semiconductor region 52) can be reduced.

The intermediate insulating film 76 is between the upper electrode 74 and the lower electrode 75, and electrically isolates the upper electrode 74 and the lower electrode 75. More specifically, the intermediate insulating film 76 covers the lower electrode 75 exposed from the lower insulating film 73 in a region between upper electrode 74 and the lower electrode 75. The intermediate insulating film 76 is connected to the upper insulating film 72 and the lower insulating film 73. The intermediate insulating film 76 preferably includes a silicon oxide film. The intermediate insulating film 76 in particular preferably includes a silicon oxide film formed by an oxide of the lower electrode 75.

The intermediate insulating film 76 has an intermediate thickness TM in the normal direction Z. The intermediate thickness TM is less than the second thickness T2 of the insulating film 73 (TM<T2). The intermediate thickness TM can be between about 0.01 μm and about 0.05 μm. The intermediate thickness TM is preferably between about 0.02 μm and about 0.04 μm.

A pair of channel elements 62 respectively form strip shapes extending along the second direction Y on both sides of each of the trench structures 61. The pair of channel elements 62 have a length less than a length of the trench structure 61 along the second direction Y. An entire region of the pair of channel elements 62 faces the upper electrode 74 across the upper insulating film 72. Each of the pair of channel elements 62 has a channel width equivalent to a value ½ times the trench interval IT.

The pair of channel elements 62 include at least one n-type source region 77 formed in the surface layer of the body region 58. The number of the source region 77 included in the pair of channel elements 62 can be any as desired. In this embodiment, each of the pair of channel elements 62 includes multiple source regions 77. All of the source regions 77 included in each of the unit elements 60 form the third sources TS of each of the unit transistors 10.

An n-type impurity concentration of the source region 77 is greater than the n-type impurity concentration of the second semiconductor region 52. The n-type impurity concentration of the source region 77 can be between about 1×10¹⁸ cm⁻³ and about 1×10²¹ cm⁻³. The multiple source regions 77 are formed at an interval from the bottom of the body region 58 in a region on the side of the first main surface 3, and face the upper electrode 74 across the upper insulating film 72. The multiple source regions 77 are arranged at intervals along the second direction Y in each of the channel elements 62. That is to say, the multiple source regions 77 are arranged at intervals along the trench structures 61 on both sides of the corresponding trench structures 61.

The pair of channel elements 62 include at least one p-type contact region 78 formed in a region different from the source region 77 in the surface layer of the body region 58. The number of the contact region 78 included in the pair of channel elements 62 can be any as desired. In this embodiment, each of the pair of channel elements 62 includes multiple contact regions 78. A p-type impurity concentration of the contact region 78 is greater than a p-type impurity concentration of the body region 58. The p-type impurity concentration of the contact region 78 can be between about 1×10¹⁸ cm⁻³ and about 1×10²¹ cm⁻³.

The multiple contact regions 78 are formed at an interval from the bottom of the body region 58 in a region on the side of the first main surface 3, and face the upper electrode 74 across the upper insulating film 72. The multiple contact regions 78 are formed to be alternately arranged with the multiple source regions 77 along the second direction Y in a manner of sandwiching one source region 77. That is to say, the multiple contact regions 78 are arranged at intervals along the trench structures 61 on both sides of the corresponding trench structures 61.

The pair of channel elements 62 include multiple channel regions 79 formed between the multiple source regions 77 and the second semiconductor region 52 in the body region 58. On/off of the multiple channel regions 79 in the pair of channel elements 62 is controlled by one trench structure 61. The multiple channel regions 79 included in the pair of the channel elements 62 form one channel of the unit transistor 10. Thus, one unit element 60 functions as one unit transistor 10.

In this embodiment, the two unit elements 60 disposed on both sides along the first direction X in the first device region 6 do not include the source region 77 in the channel element 62 on the side of the trench separation structure 53. According to the structure above, a leakage current between the trench structure 61 and the trench separation structure 53 can be suppressed. In this embodiment, the two unit elements 60 disposed on both sides include only the contact region 78 (hereinafter referred to as “an outermost contact region 78”) in the channel element 62 on the side of the trench separation structure 53. The outermost contact region 78 is formed at an interval from the trench separation structure 53 toward the side of the trench structure 61, and is connected to the sidewall of the corresponding trench structure 61. The outermost contact region 78 can also be formed as a strip shape extending along the sidewall of the corresponding trench structure 61.

The main transistor 8 includes two (n=2) system transistors 9 collectively formed in the first device region 6. The two system transistors 9 include the first system transistor 9A and the second system transistor 9B. The first system transistor 9A includes multiple (22 in this embodiment) first unit transistors 10A selectively systemized from the multiple unit transistors 10, as individual control targets.

In addition to the first unit transistors 10A, the second system transistor 9B includes multiple (22 in this embodiment) second unit transistors 10B selectively systemized from the multiple unit transistors 10, as individual control targets. The number of the second unit transistors 10B can be different from the number of the first unit transistors 10A. The number of the second unit transistors 10B is preferably equal to the number of the first unit transistors 10A.

In the description below, “the unit element 60”, “the trench structure 61”, “the channel element 62”, “the trench 71”, “the upper insulating film 72”, “the lower insulating film 73”, “the upper electrode 74”, “the lower electrode 75”, “the intermediate insulating film 76”, “the source region 77”, “the contact region 78”, and “the channel region 79” of the first unit transistor 10A are referred to as “a first unit element 60A”, “a first trench structure 61A”, “a first channel element 62A”, “a first trench 71A”, “a first upper insulating film 72A”, “a first lower insulating film 73A”, “a first upper electrode 74A”, “a first lower electrode 75A”, “a first intermediate insulating film 76A”, “a first source region 77A”, “a first contact region 78A” and “a first channel region 79A”, respectively. A first gate signal G1 is input to the first upper electrode 74A and the first lower electrode 75A.

In the description below, “the unit element 60”, “the trench structure 61”, “the channel element 62”, “the trench 71”, “the upper insulating film 72”, “the lower insulating film 73”, “the upper electrode 74”, “the lower electrode 75”, “the intermediate insulating film 76”, “the source region 77”, “the contact region 78”, and “the channel region 79” of the second unit transistor 10B are referred to as “a second unit element 60B”, “a second trench structure 61B”, “a second channel element 62B”, “a second trench 71B”, “a second upper insulating film 72B”, “a second lower insulating film 73B”, “a second upper electrode 74B”, “a second lower electrode 75B”, “a second intermediate insulating film 76B”, “a second source region 77B”, “a second contact region 78B” and “a second channel region 79B”, respectively. A second gate signal G2 electrically independent from the first gate signal G1 is input to the second upper electrode 74B and the second lower electrode 75B.

The first system transistor 9A includes at least one first composite element 81. The number of the first composite element 81 can be any as desired, and is adjusted according to a size of the first device region 6 (a total number of the unit transistors 10). In this embodiment, the first system transistor 9A includes multiple (11 in this embodiment) first composite elements 81. Each of the multiple first composite elements 81 includes α (α≥2) first unit transistors 10A (the first unit elements 60A) arranged adjacent to the first main surface 3 in the plan view. The multiple first composite elements 81A are arranged at intervals along the first direction X in the plan view.

The second system transistor 9B includes at least one second composite element 82. The number of the second composite element 82 can be any as desired, and is adjusted according to the size of the first device region 6 (the total number of the unit transistors 10). The number of the second composite elements 82 can be different from the number of the first composite elements 81. The number of the second composite elements 82 is preferably equal to the number of the first composite elements 81. In this embodiment, the second system transistor 9B includes multiple (11 in this embodiment) second composite elements 82. Each of the multiple second composite elements 82 includes β (β≥2) second unit transistors 10B (the second unit elements 60B) arranged adjacent to the first main surface 3 in the plan view.

The multiple second composite elements 82 are respectively disposed adjacent to the multiple first composite elements 81 in the plan view. Specifically, the multiple second composite elements 82 are respectively disposed in regions between and are close to the multiple first composite elements 81 in the plan view. More specifically, the multiple second composite elements 82 are alternately arranged with the multiple first composite elements 81 along the first direction X in a manner of sandwiching one first composite element 81 in the plan view.

The number of the first unit transistors 10A included in one first composite element 81 can also be set as 1 (α=1), and the number of the second unit transistors 10B included in one second composite element 82 is set as 1 (β=1). That is to say, the multiple second unit transistors 10B can also be alternately arranged with the multiple first unit transistors 10A in a manner of sandwiching one unit transistor 10 in the plan view.

However, in this case, the number of opposing first unit transistors 10A and second unit transistors 10B is increased. As a result, a risk of short-circuitry between the first unit transistor 10A and the second unit transistor 10B that are close to each other caused by such as process errors is increased. The term “short-circuitry” herein refers to a short circuit between the first trench structure 61A (the third gate TG) of the first unit transistor 10A and the second trench structure 61B (the third gate TG) of the second unit transistor 10B (also referring to the circuit diagram in FIG. 6).

For example, in the event of short-circuitry between one first unit transistor 10A and one nearby second unit transistor 10B, short-circuitry is generated in all of the first unit transistors 10A and all of the second unit transistors 10B. That is to say, the first system transistor 9A and the second system transistor 9B function as one system transistor 9, and as a result, the first system transistor 9A and the second system transistor 9B do not form the main transistor 8 of two systems (also referring to the circuit diagram in FIG. 6).

Thus, the number of the first unit transistors 10A included in one first composite element 81 is preferably more than or equal to 2 (α≥2), and the number of the second unit transistors 10B included in one second composite element 82 is preferably more than or equal to 2 (β≥2). According to the structure above, the number of opposing first unit transistors 10A and second unit transistors 10B can be reduced. As a result, a risk of short-circuitry between the first unit transistor 10A and the second unit transistor 10B that are close to each other can be reduced.

In this case, the electrode surface of the first upper electrode 74A associated with the first system transistor 9A is preferably separated from the first main surface 3 toward the bottom wall of the first trench 71A by an interval of more than or equal to 2000 Å (preferably between about 2500 Å and about 4500 Å) in the depth direction of the first trench 71A. The depth position of the electrode surface of the first upper electrode 74A is adjusted to a depth position that does not degrade characteristics of the gate threshold voltage of the first unit transistor 10A.

Similarly, the electrode surface of the second upper electrode 74B associated with the second system transistor 9B is preferably separated from the first main surface 3 toward the bottom wall of the second trench 71B by an interval of more than or equal to 2000 Å (preferably between about 2500 Å and about 4500 Å) in the depth direction of the second trench 71B. The depth position of the electrode surface of the second upper electrode 74B is adjusted to a depth position that does not degrade characteristics of the gate threshold voltage of the second unit transistor 10B.

According to the structures above, the first upper electrode 74A can be appropriately separated from the second upper electrode 74B and be buried in the first trench 71A, and the second upper electrode 74B can be appropriately separated from the first upper electrode 74A and be buried in the second trench 71B. Accordingly, the risk of short-circuitry between the first upper electrode 74A and the second upper electrode 74B can be appropriately reduced. Moreover, the first source region 77A (the first channel region 79A) can appropriately face the first upper electrode 74A, and the second source region 77B (the second channel region 79B) can appropriately face the second upper electrode 74B.

The first unit transistor 10A (specifically, the first channel region 79A) becomes a heat generating source in the first device region 6. Thus, the number of the first unit transistors 10A defines the amount of heat generation of one first composite element 81, and the configuration of the multiple first composite elements 81 define a heat generating portion in the first device region 6. That is to say, if the number of the first unit transistors 10A forming one first composite element 81 is increased, the amount of heat generation in the one first composite element 81 is also increased. Moreover, when multiple first composite elements 81 are disposed in an adjacent manner, the heat generating portion of the first device region 6 becomes localized.

Thus, the number of the first unit transistors 10A is preferably less than or equal to 4 (α≤4). According to the structure above, a rise in a local temperature of one first composite element 81 can be suppressed. Considering the risk of short-circuitry as well as the amount of heat generation, the number of the first unit transistors 10A is in particular preferably 2 (α=2). The multiple first composite elements 81 are preferably arranged equidistantly in a region between one end of the first device region 6 and the other end thereof. According to the structure above, heat generating portions caused by the multiple first composite elements 81 in the first device region 6 can be spaced farther apart, thereby suppressing a rise in the local temperature of the first device region 6.

In each of the first composite elements 81, the multiple first channel regions 79A (the first source regions 77A) arranged on the side of one first trench structure 61A preferably face a region between the multiple first channel regions 79A (the first source regions 77A) arranged on the side of another first trench structure 61A along the first direction X. According to the structure above, starting points of heat generation in each of the first composite elements 81 can be spaced farther apart. Accordingly, a rise in the local temperature of each of first composite elements 81 can be suppressed.

In this case, in each of the first unit elements 60A, the multiple first channel regions 79A formed in one first channel element 62A preferably face the multiple first channel regions 79A formed in another first channel element 62A across the corresponding first trench structure 61A. In each of the first composite elements 81, the multiple first channel regions 79A formed in a region between one pair of first trench structures 61A are preferably arranged to be shifted from each other along the second direction Y in the plan view. As a matter of course, in each of the first unit elements 60A, the multiple first channel regions 79A formed in one first channel element 62A can also face a region between the multiple first channel regions 79A formed in another first channel element 62A across the corresponding first trench structure 61A.

In each of the first unit elements 60A, the multiple first contact regions 78A formed in one first channel element 62A can also face the multiple first contact regions 78A formed in another first channel element 62A across the corresponding first trench structure 61A. In each of the first composite elements 81, the multiple first contact regions 78A arranged on the side of one first trench structure 61A can also face a region between the multiple first contact regions 78A arranged on the side of another first trench structure 61A along the first direction X.

In each of the first composite elements 81, the multiple first contact regions 78A formed in a region between one pair of first trench structures 61A can also be arranged to be shifted from each other along the second direction Y in the plan view. Moreover, the multiple first contact regions 78A can also face the multiple first source regions 77A along the first direction X in the plan view.

The multiple second composite elements 82 are preferably arranged equidistantly in a region between one end of the first device region 6 and the other end thereof. According to the structure above, heat generating portions caused by the multiple second composite elements 82 in the first device region 6 can be spaced farther apart, thereby suppressing a rise in the local temperature of the first device region 6. In this case, preferably, at least one second composite element 82 is disposed close to at least one first composite element 81. According to the structure above, a situation that in the first composite element 81 and the second composite element 82 that are close to each other, either of the two elements is turned on and the other is turned off, can be achieved. Accordingly, a rise in the local temperature caused by the first composite element 81 and the second composite element 82 can be suppressed.

In this case, at least one second composite element 82 is preferably disposed in a region between two adjacent first composite elements 81. Further, in this case, in particular preferably, the multiple second composite elements 82 are alternately arranged with the multiple first composite elements 81 in a manner of sandwiching one first composite element 81. According to the structures above, two first composite elements 81 close to each other can be separated by an amount equivalent to the second composite element 82. Accordingly, heat generating portions caused by the multiple first composite elements 81 and the multiple second composite elements 82 can be appropriately spaced farther apart, thereby suppressing a rise in the local temperature of the first device region 6.

In each of the second composite elements 82, the multiple second channel regions 79B (the second source regions 77B) arranged on the side of one second trench structure 61B preferably face a region between the multiple second channel regions 79B (the second source regions 77B) arranged on the side of another second trench structure 61B along the first direction X. According to the structure above, starting points of heat generation in each of the second composite elements 82 can be spaced farther apart. Accordingly, a rise in the local temperature of each of the second composite elements 82 can be suppressed.

In this case, in each of the second unit elements 60B, the multiple second channel regions 79B formed in one second channel element 62B preferably face the multiple second channel regions 79B formed in another second channel element 62B across the corresponding second trench structure 61B. In each of the second composite elements 82, the multiple second channel regions 79B formed in a region between one pair of second trench structures 61B are preferably arranged to be shifted from each other along the second direction Y in the plan view.

In an inter-trench region of each of the first trench structures 61A and each of the second trench structures 61B, the multiple second channel regions 79B are preferably arranged as shifted with respect to the multiple first channel regions 79A along the second direction Y. That is to say, the multiple second channel regions 79B preferably face a region between the multiple first contact regions 78A in the inter-trench regions along the first direction X. According to the structure above, starting points of heat generation in inter-trench regions can be spaced farther apart. Accordingly, a rise in the local temperature of the inter-trench regions can be suppressed.

In each of the second unit elements 60B, the multiple second contact regions 78B formed in one second channel element 62B can also face the multiple second contact regions 78B formed in another second channel element 62B across the corresponding second trench structure 61B. In each of the second composite elements 82, the multiple second contact regions 78B arranged on the side of one second trench structure 61B can also face a region between the multiple second contact regions 78B arranged on the side of another second trench structure 61B along the first direction X. As a matter of course, in each of the second unit elements 60B, the multiple second channel regions 79B formed in one second channel element 62B can also face a region between the multiple second channel regions 79B formed in another second channel element 62B across the corresponding second trench structure 61B.

In each of the second composite elements 82, the multiple second contact regions 78B formed in a region between one pair of second trench structures 61B can also be arranged to be shifted from each other along the second direction Y in the plan view. The multiple second contact regions 78B can also face the multiple second source regions 77B along the first direction X in the plan view.

The main transistor 8 of n systems has a total channel ratio RT. The total channel ratio RT is a ratio of a total planar area of all of the channel regions 79 to a planar area of all of the channel elements 62. The planar area of each of the channel regions 79 is defined by a planar area of each of the source regions 77. The total channel ratio RT is adjusted within a range between about 0% and about 100%. The total channel ratio RT is preferably adjusted within a range between about 25% and about 75%.

The total channel ratio RT is divided into n system channel ratios RS by the n system transistors 9. The total channel ratio RT of the main transistor 8 of two systems is formed by adding a first system channel ratio RSA of the first system transistor 9A and a second system channel ratio RSB of the second system transistor 9B (RT=RSA+RSB). The first system channel ratio RSA is a ratio of a total planar area of all of the first channel regions 79A to the total planar area of all of the channel elements 62. The second system channel ratio RSB is a ratio of a total planar area of all of the second channel regions 79B to the total planar area of all of the channel elements 62.

The planar area of each of the first channel regions 79A is defined by the planar area of each of the first source regions 77A, and the planar area of each of the second channel regions 79B is defined by the planar area of each of the second source regions 77B. The first system channel ratio RSA is adjusted via an arrangement pattern of the first source regions 77A and the first contact regions 78A. The second system channel ratio RSB is adjusted via an arrangement pattern of the second source regions 77B and the second contact regions 78B.

The first system channel ratio RSA is divided into multiple first channel ratios RCA by the multiple first composite elements 81. The first channel ratio RCA is a ratio of a total planar area of the multiple first channel regions 79A in each of the first composite elements 81 to the total planar area of all of the channel elements 62. The first system channel ratio RSA is formed by a sum of the multiple first channel ratios RCA. The multiple first composite elements 81 preferably have first channel ratios RCA equal to one another. In each of the first unit transistors 10A, the multiple first channel regions 79A can be formed to have first areas per unit area different from or equal to one another.

The second system channel ratio RSB is divided into multiple second channel ratios RCB by the multiple second composite elements 82. The second channel ratio RCB is a ratio of a total planar area of the multiple second channel regions 79B in each of the second composite elements 82 to the total planar area of all of the channel elements 62. The multiple second composite elements 82 are preferably formed by a sum of the multiple second channel ratios RCB. The multiple second composite elements 82 preferably have second channel ratios RCB equal to one another. In each of the second unit transistors 10B, the multiple second channel regions 79B can be formed to have second areas per unit area different from or equal to one another. From the perspective of each unit area, the second areas can also be equal to or different from the first areas of the multiple first channel regions 79A.

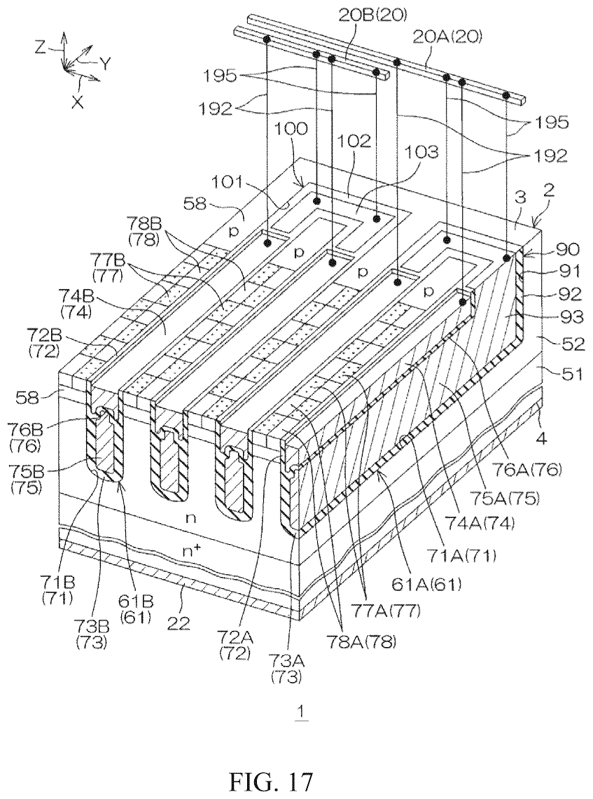

The second system channel ratio RSB can also be substantially equivalent to the first system channel ratio RSA (RSA [symbol] RSB). The second system channel ratio RSB can also be greater than the first system channel ratio RSA (RSA<RSB). The second system channel ratio RSB can also be less than the first system channel ratio RSA (RSB<RSA). In the description below, configuration examples of the first channel region 79A and the second channel region 79B are shown in FIG. 17 to FIG. 20.

FIG. 17 shows a perspective cross-sectional view of a first configuration example showing all of a main portion of the main transistor 8, the first channel region 79A and the second channel region 79B. In this configuration example, the total channel ratio RT is 50%, the first system channel ratio RSA is 25%, and the second system channel ratio RSB is 25%.

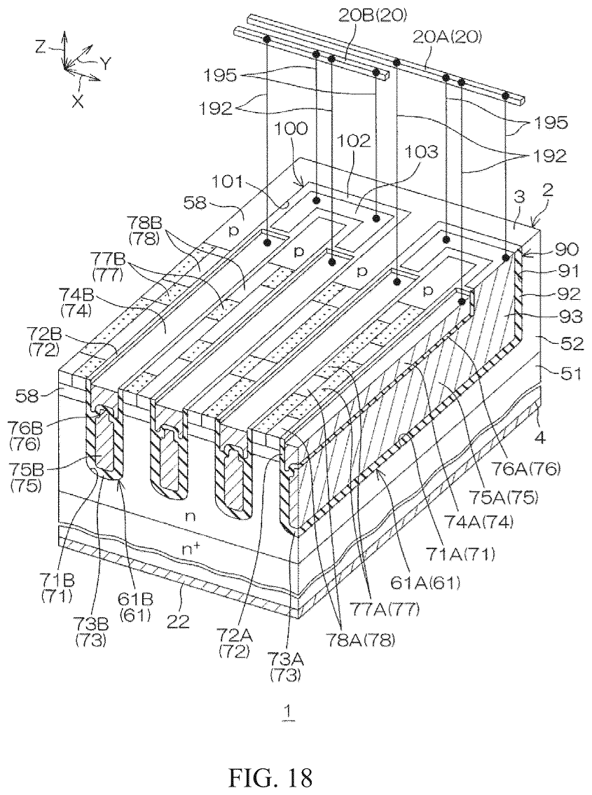

FIG. 18 shows a perspective cross-sectional view of a second configuration example showing all of a main portion of the main transistor 8, the first channel region 79A and the second channel region 79B. In this configuration example, the total channel ratio RT is 50%, the first system channel ratio RSA is 37.5%, and the second system channel ratio RSB is 12.5%.

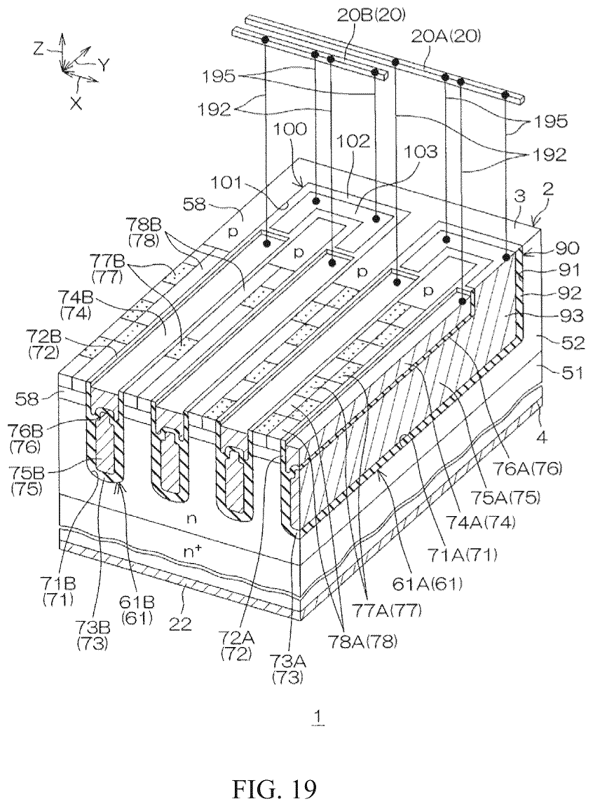

FIG. 19 shows a perspective cross-sectional view of a third configuration example showing all of a main portion of the main transistor 8, the first channel region 79A and the second channel region 79B. In this configuration example, the total channel ratio RT is 33%, the first system channel ratio RSA is 24.7%, and the second system channel ratio RSB is 8.3%.

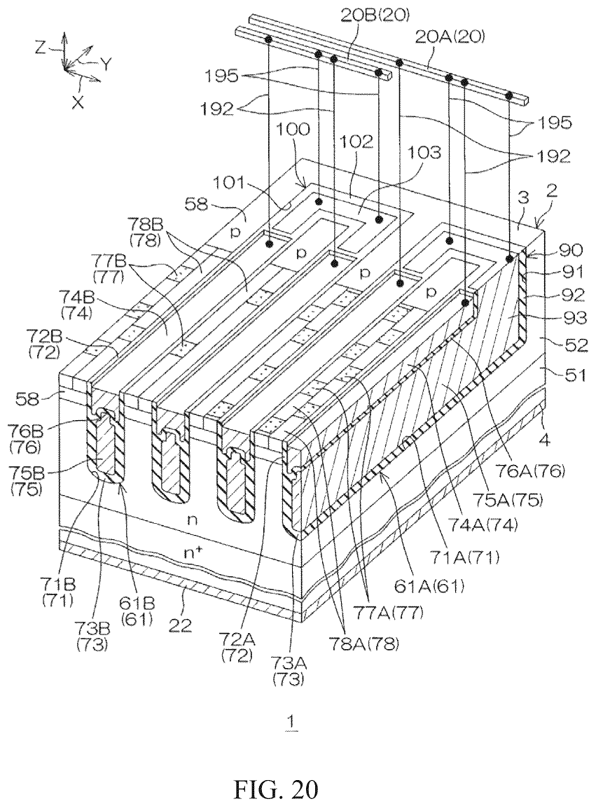

FIG. 20 shows a perspective cross-sectional view of a fourth configuration example showing all of a main portion of the main transistor 8, the first channel region 79A and the second channel region 79B. In this configuration example, the total channel ratio RT is 25%, the first system channel ratio RSA is 18.7%, and the second system channel ratio RSB is 6.3%.

Again referring to FIG. 10 to FIG. 16, the main transistor 8 includes multiple pairs (11 pairs and hence a total of 22 in this embodiment) of first trench connection structures 90 formed in the first main surface 3 in the first device region 6. Each pair of the multiple pairs of first trench connection structures 90 include the first trench connection structure 90 on one side (the side of the first side surface 5A) and the first trench connection structure 90 on the other side (the side of the second side surface 5B) facing each other across the corresponding first composite element 81 along the second direction Y.

The first trench connection structure 90 on the one side connects the first ends 63 of the multiple (one pair in this embodiment) first trench structures 61A into an arched shape in the plan view. The first trench connection structure 90 on the other side connects the second ends 64 of the multiple (one pair in this embodiment) first trench structures 61A into an arched shape in the plan view. The pair of first trench connection structures 90 and the multiple (one pair in this embodiment) first trench structures 61A forming one first composite element 81 form one loop-shaped trench structure.

Apart from connecting the second ends 64 of the first trench structures 61A, the first trench connection structure 90 on the other side has a structure same as the first trench connection structure 90 on the one side. The configuration of one first trench connection structure 90 on the one side is described below, while configuration details of the first trench connection structure 90 on the other side are omitted.

The first trench connection structure 90 on the one side has a first portion 90A extending along the first direction X and multiple (one pair in this embodiment) second portions 90B extending along the second direction Y. The first portion 90A faces the multiple first ends 63 in the plan view. The multiple second portions 90B extend from the first portion 90A toward the multiple first ends 63, and are connected to the multiple first ends 63.

The first trench connection structure 90 on the one side has a connection width WC and a connection depth DC. The connection width WC is a width in a direction perpendicular to an extension direction of the first trench connection structure 90. The connection width WC is preferably substantially equivalent to the trench width W of the trench structure 61 (WC [symbol] W). The connection depth DC is preferably substantially equivalent to the trench depth D of the trench structure 61 (DC [symbol] D). A depth/width ratio DC/WC of the first trench connection structure 90 is preferably substantially equivalent to the depth/width ratio D/W of the trench structure 61 (DC/WC [symbol] D/W). A bottom wall of the first trench connection structure 90 is preferably formed at an interval of between about 1 μm and about 5 μm from the bottom of the second semiconductor region 52. Moreover, to ensure a space of a plug electrode 195 described below, the connection width WC and the connection depth DC can also be greater than the trench width W and the trench depth D, respectively. That is to say, it can also be set that WC>W and DC>D.

The first trench connection structure 90 on the one side has a single-electrode structure, and includes a first connection trench 91, a first connection insulating film 92, a first connection electrode 93 and a first covering insulating film 94. The first connection trench 91 extends in an arched shape to be in communication with the first ends 63 of the multiple first trenches 71A in the plan view, and is etched from the first main surface 3 toward the second main surface 4. The first connection trench 91 defines the first portion 90A and the second portions 90B of the first trench connection structure 90. The first connection trench 91 is formed at an interval from the bottom of the second semiconductor region 52 toward the side of the first main surface 3.

The first connection trench 91 includes a sidewall and a bottom wall. An angle formed between the sidewall of the first connection trench 91 and the first main surface 3 in the semiconductor chip 2 can be between about 90° and about 92°. The first connection trench 91 can also be formed to have a front end tapered shape with an opening width that narrows from an opening toward the bottom wall. Corners of the bottom wall of the first connection trench 91 are preferably formed to have a curved shape. The entire bottom wall of the first connection trench 91 can be also formed to have a curved shape facing the second main surface 4. The sidewall and the bottom wall of the first connection trench 91 are smoothly connected to the sidewall and the bottom wall of the first trench 71A.

The first connection insulating film 92 is formed on a wall surface of the first connection trench 91. More specifically, the first connection insulating film 92 is formed film-like in an entire region of the wall surface of the first connection trench 91, and defines a recessed space in the first connection trench 91. The first connection insulating film 92 extends at the first portion 90A of the first connection trench 91 along the first direction X. The first connection insulating film 92 extends at the second portions 90B of the first connection trench 91 along the second direction Y. The first connection insulating film 92 is connected to the first upper insulating film 72A and the first lower insulating film 73A at a communication portion of the first connection trench 91 and the first trench 71A. The first connection insulating film 92 includes a silicon oxide film. The first connection insulating film 92 in particular preferably includes a silicon oxide film formed by an oxide of the semiconductor chip 2.

The first connection insulating film 92 has a third thickness T3. The third thickness T3 is a thickness along the normal direction of the wall surface of the first connection trench 91. The third thickness T3 is greater than the first thickness T1 of the first upper insulating film 72A (T1<T3). The third thickness T3 can also be substantially equivalent to the second thickness T2 of the lower insulating film 73 (T2 [symbol] T3). The third thickness T3 can also be substantially equivalent to the separation thickness TI of the separation insulating film 55 (T3 [symbol] TI). The third thickness T3 can be between about 0.1 μm and about 1 μm. The third thickness T3 is preferably between about 0.15 μm and about 0.65 μm. The thickness of a portion of the first connection insulating film 92 covering the bottom wall of the first connection trench 91 can be less than the thickness of a portion covering the sidewall of the first connection trench 91.

The first connection electrode 93 is separated by the first connection insulating film 92 as an integrated member and is buried in the first connection trench 91. In this embodiment, the first connection electrode 93 includes a conductive polycrystalline silicon. The first connection electrode 93 extends at the first portion 90A of the first connection trench 91 along the first direction X. The first connection electrode 93 extends at the second portions 90B of the first connection trench 91 along the second direction Y. The first connection electrode 93 is connected to the first lower electrode 75A at a communication portion of the first connection trench 91 and the first trench 71A.

The first connection electrode 93 is electrically insulated from the first upper electrode 74A across the first intermediate insulating film 76A. That is to say, the first connection electrode 93 includes a lead-out portion, which is led out from the first trench 71A to the first connection trench 91 across the first connection insulating film 92 and the first intermediate insulating film 76A in the first lower electrode 75A. The first gate signal G1 is transmitted to the first lower electrode 75A via the first connection electrode 93. That is to say, the same first gate signal G1 is applied to the first connection electrode 93 in synchronization with the first upper electrode 74A.

The first connection electrode 93 has an electrode surface (a first connection electrode surface) exposed from the first connection trench 91. The electrode surface of the first connection electrode 93 can be recessed toward the bottom wall of the first connection trench 91 to form a curved shape. The electrode surface of the first connection electrode 93 is preferably positioned (protruded) closer to the side of the first main surface 3 than the depth position of the electrode surface of the upper electrode 74 of the trench structure 61 in a depth direction of the first connection trench 91. The electrode surface of the first connection electrode 93 is preferably separated from the first main surface 3 toward the bottom wall of the first connection trench 91 by an interval of between about 0 Å and about 2000 Å. The electrode surface of the first connection electrode 93 is in particular preferably separated from the first main surface 3 toward the bottom wall of the first connection trench 91 by an interval of less than or equal to 1000 Å.

Moreover, in FIG. 14 to FIG. 15, the entire electrode surface of the first connection electrode 93 is closer to the bottom than the first main surface 3, but the electrode surface of the first connection electrode 93 can also have a portion closer to the top than the first main surface 3. For example, the first connection electrode 93 can also have a protruding portion extending to closer to the top than the first main surface 3, and has the recessed and curved electrode surface at the protruding portion.

The first covering insulating film 94 as a film covers the electrode surface of the first connection electrode 93 in the first connection trench 91. The first covering insulating film 94 suppresses short-circuitry of the first connection electrode 93 with other electrodes. The first covering insulating film 94 is connected to the first connection insulating film 92. The first covering insulating film 94 preferably includes a silicon oxide film. The first covering insulating film 94 in particular preferably includes a silicon oxide film formed by an oxide of the first connection electrode 93. That is to say, preferably, the first covering insulating film 94 includes a polysilicon oxide, and the first connection insulating film 92 includes a monosilicon oxide.

The main transistor 8 includes multiple pairs (11 pairs and hence a total of 22 in this embodiment) of second trench connection structures 100 formed in the first main surface 3 in the first device region 6. Each pair of the multiple pairs of second trench connection structures 100 include the second trench connection structure 100 on one side (the side of the first side surface 5A) and the second trench connection structure 100 on the other side (the side of the second side surface 5B) facing each other across the corresponding second composite element 82 along the second direction Y.

The second trench connection structure 100 on the one side connects the first ends 63 of the multiple (one pair in this embodiment) second trench structures 61B into an arched shape in the plan view. The second trench connection structure 100 on the other side connects the second ends 64 of the multiple (one pair in this embodiment) second trench structures 61B into an arched shape in the plan view. The pair of second trench connection structures 100 and the multiple (one pair in this embodiment) second trench structures 61B forming one second composite element 82 form one loop-shaped trench structure.

Apart from connecting the second ends 64 of the second trench structures 61B, the second trench connection structure 100 on the other side has a structure same as the second trench connection structure 100 on the one side. The configuration of one second trench connection structure 100 on the one side is described below, while configuration details of the second trench connection structure 100 on the other side are omitted.

The second trench connection structure 100 on the one side has a first portion 100A extending along the first direction X and multiple (one pair in this embodiment) second portions 100B extending along the second direction Y. The first portion 100A faces the multiple first ends 63 in the plan view. The multiple second portions 100B extend from the first portion 100A toward the multiple first ends 63, and are connected to the multiple first ends 63. Similar to each of the first trench connection structures 90, the second trench connection structure 100 on the one side has the connection width WC and the connection depth DC.

The second trench connection structure 100 on the one side has a single-electrode structure, and includes a second connection trench 101, a second connection insulating film 102, a second connection electrode 103 and a second covering insulating film 104. The second connection trench 101 extends in an arched shape to be in communication with the first ends 63 of the pair of second trenches 71B in the plan view, and is etched from the first main surface 3 toward the second main surface 4. The second connection trench 101 defines the first portion 100A and the second portions 100B of the second trench connection structure 100. The second connection trench 101 is formed at an interval from the bottom of the second semiconductor region 52 toward the side of the first main surface 3.

The second connection trench 101 includes a sidewall and a bottom wall. An angle formed between the sidewall of the second connection trench 101 and the first main surface 3 in the semiconductor chip 2 can be between about 90° and about 92°. The second connection trench 101 can also be formed to have a front end tapered shape with an opening width that narrows from an opening toward the bottom wall. Corners of the bottom wall of the second connection trench 101 are preferably formed to have a curved shape. The entire bottom wall of the second connection trench 101 can be also formed to have a curved shape facing the second main surface 4. The sidewall and the bottom wall of the second connection trench 101 are smoothly connected to the sidewall and the bottom wall of the second trench 71B.

The second connection insulating film 102 is formed on a wall surface of the second connection trench 101. More specifically, the second connection insulating film 102 is formed film-like in an entire region of the wall surface of the second connection trench 101, and defines a recessed space in the second connection trench 101. The second connection insulating film 102 extends at the first portion 100A of the second connection trench 101 along the first direction X. The second connection insulating film 102 extends at the second portions 100B of the second connection trench 101 along the second direction Y. The second connection insulating film 102 includes a silicon oxide film. The second connection insulating film 102 in particular preferably includes a silicon oxide film formed by an oxide of the semiconductor chip 2. Similar to the first connection insulating film 92, the second connection insulating film 102 has the third thickness T3.

The second connection electrode 103 is separated by the second connection insulating film 102 as an integrated member and is buried in the second connection trench 101. In this embodiment, the second connection electrode 103 includes a conductive polycrystalline silicon. The second connection electrode 103 extends at the first portion 100A of the second connection trench 101 along the first direction X. The second connection electrode 103 extends at the second portions 100B of the second connection trench 101 along the second direction Y. The second connection electrode 103 is connected to the second lower electrode 75B at a communication portion of the second connection trench 101 and the second trench 71B.

The second connection electrode 103 is electrically insulated from the second upper electrode 74B across the second intermediate insulating film 76B. That is to say, the second connection electrode 103 includes a lead-out portion, which is led out from the second trench 71B to the second connection trench 101 across the second connection insulating film 102 and the second intermediate insulating film 76B in the second lower electrode 75B. The second gate signal G2 is transmitted to the second lower electrode 75B via the second connection electrode 103. That is to say, the same second gate signal G2 is applied to the second connection electrode 103 in synchronization with the second upper electrode 74B.

The second connection electrode 103 has an electrode surface (a second connection electrode surface) exposed from the second connection trench 101. The electrode surface of the second connection electrode 103 can be also recessed toward the bottom wall of the second connection trench 101 to form a curved shape. The electrode surface of the second connection electrode 103 is preferably positioned (protruded) closer to the side of the first main surface 3 than the depth position of the electrode surface of the upper electrode 74 of the trench structure 61 in a depth direction of the second connection trench 101. The electrode surface of the second connection electrode 103 is preferably separated from the first main surface 3 toward the bottom wall of the second connection trench 101 by an interval of between about 0 Å and about 2000 Å. The electrode surface of the second connection electrode 103 is in particular preferably separated from the first main surface 3 toward the bottom wall of the second connection trench 101 by an interval of less than or equal to 1000 Å.

The second covering insulating film 104 as a film covers the electrode surface (a second connection electrode surface) of the second connection electrode 103 in the second connection trench 101. The second covering insulating film 104 suppresses short-circuitry of the second connection electrode 103 with other electrodes. The second covering insulating film 104 is connected to the second connection insulating film 102. The second covering insulating film 104 preferably includes a silicon oxide film. The second covering insulating film 104 in particular preferably includes a silicon oxide film formed by an oxide of the second connection electrode 103. That is to say, preferably, the second covering insulating film 104 includes a polysilicon oxide, and the second connection insulating film 102 includes a monosilicon oxide.

The semiconductor device 1 further includes a main source wiring 198 disposed in the interlayer insulating layer 19. The main source wiring 198 is electrically connected to the source terminal 23, the trench separation structure 53 and the multiple channel elements 62. More specifically, referring to FIG. 13, FIG. 15 and FIG. 16, the main source wiring 198 is connected to the isolation electrode 56 of the trench separation structure 53 via multiple plug electrodes 191 disposed in the interlayer insulating layer 19. Referring to FIG. 13, the main source wiring 198 is connected to the source region 77 and the contact region 78 of the channel element 62 via a plug electrode 193 disposed in the interlayer insulating layer 19.

The semiconductor device 1 further includes the first main gate wiring 20A disposed in the interlayer insulating layer 19. The first main gate wiring 20A is electrically connected to the first trench structure 61A. More specifically, referring to FIG. 15, the first main gate wiring 20A is electrically connected to the first upper electrode 74A and the first lower electrode 75A of the first trench structure 61A via a plug electrode 192 and a plug electrode 195 disposed in the interlayer insulating layer 19, respectively.

The semiconductor device 1 further includes the second main gate wiring 20B disposed in the interlayer insulating layer 19. The second main gate wiring 20B is electrically connected to the second trench structure 61B. More specifically, referring to FIG. 16, the second main gate wiring 20B is connected to the second upper electrode 74B and the second lower electrode 75B of the second trench structure 61B via the plug electrode 192 and the plug electrode 195 disposed in the interlayer insulating layer 19, respectively.

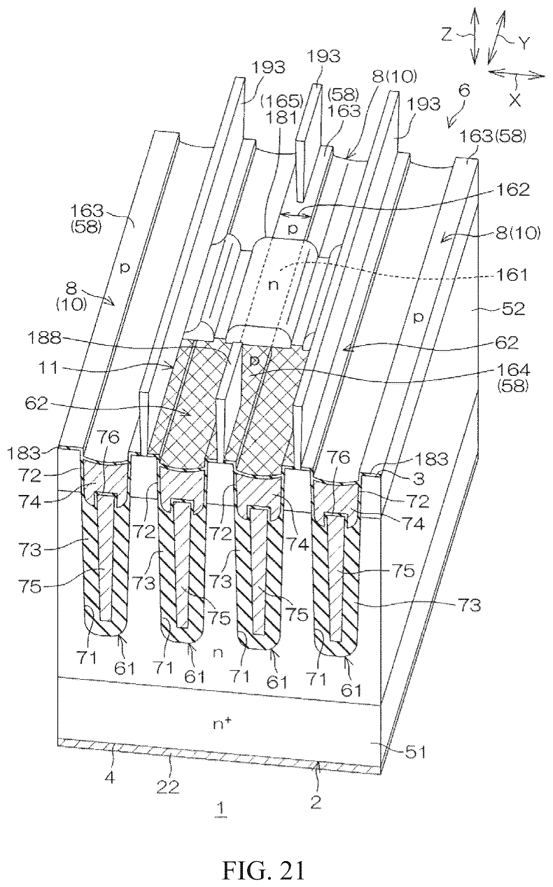

FIG. 21 shows a perspective cross-sectional view of the semiconductor device 1 near a separation portion 161 separating the main transistor 8 and the monitoring transistor 11. For the sake of clarity, a region of the monitoring transistor 11 is marked with crossing shading lines in FIG. 21.

Referring to FIG. 21, the semiconductor device 1 includes the monitoring transistor 11 formed in the first main surface 3 in the first device region 6. The monitoring transistor 11 is collectively formed with main transistor 8 in the first main surface 3 in the first device region 6. The monitoring transistor 11 is formed inside the first device region 6 to be separated from the trench separation structure 53 (referring to FIG. 10). The monitoring transistor 11 is preferably formed to be sandwiched by the multiple unit transistors 10 along the first direction X in the plan view.

In this embodiment, the main transistor 8 and the monitoring transistor 11 have the channel elements 62 with the same structure. For example, the channel element 62 of the main transistor 8 can also be referred to as “a main side channel element”, and the channel element 62 of the monitoring transistor 11 can also be referred to as “a monitoring side channel element”. Further, although omitted from FIG. 21, the source region 77 and the contact region 78 of the main transistor 8 can also be referred to as “a main side source region” and “a main side contact region”, respectively. The source region 77 and the contact region 78 of the monitoring transistor 11 can also be referred to as “a monitoring side source region” and “a monitoring side contact region”, respectively.

The main transistor 8 and the monitoring transistor 11 are electrically isolated by the separation portion 161. The separation portion 161 is selectively formed in an n-type impurity region of a gate space 162 sandwiched between the adjacent trench structures 61. A midway portion of the gate space 162 extending as a strip shape along the second direction Y is disconnected by the n-type impurity region (the separation portion 161). Accordingly, the p-type body region 58 formed in gate space 162 is separated into a main body region 163 and a monitoring body region 164. The source region 77 and the contact region 78 are respectively formed in the surface layers of the main body region 163 and the monitoring body region 164, but are omitted from FIG. 21.

Herein, referring to FIG. 10, the separation portion 161 includes a pair of separation portions 161 separated along the second direction Y. The body region 58 sandwiched between the pair of separation portions 161 is the monitoring body region 164 used by the monitoring transistor 11. The body region 58 located on a side opposite to the monitoring body region 164 across the pair of separation portions 161 is the main body region 163 used by the main transistor 8.

Referring to FIG. 21, a field insulating film 181 is formed on the separation portion 161. The field insulating film 181 covers the separation portion 161. Since the field insulating film 181 is thicker than a main surface insulating film 183 covering the body region 58, an insulating structure 165 (the field insulating film 181 in this embodiment) selectively raised with respect to a region above the body region 58 is formed in a region above the separation portion 161 in the normal direction Z. In this embodiment, the insulating structure 165 is formed in one pair separated from each other in the gate space 162 extending in a strip shape along the second direction Y.

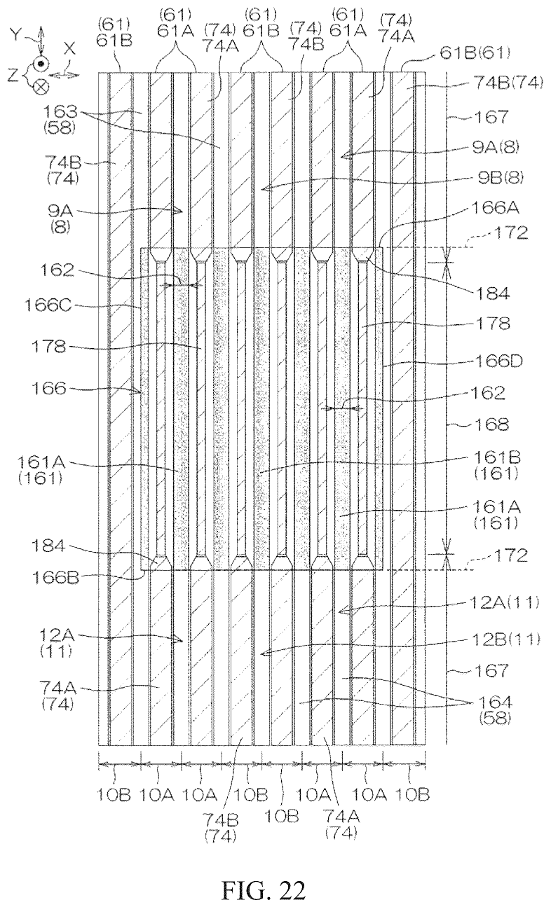

Next, the structure near the separation portion 161 is described in detail with reference to FIG. 22 to FIG. 29 below.

FIG. 22 shows a schematic plan view of a planar structure near the separation portion 161, and indicates a portion surrounded by the single-dotted line XXII in FIG. 10. In FIG. 22, a structure of one separation portion 161 of the pair of separation portions 161 in FIG. 10 is depicted; however, the structure of the other separation portion 161 has the same structure. In FIG. 22, a region occupied by the separation portion 161 is shown by regions shaded in gray.

Referring to FIG. 22, the separation portion 161 is formed in a region with a separation pattern 166 having a predetermined geometric shape. The separation pattern 166 is formed to cross the multiple unit transistors 10A and 10B along the first direction X. For example, in the plan view, the separation pattern 166 is formed to cross the multiple unit transistors 10A and 10B. The shape of the separation pattern 166 is not specifically defined, and can be any of a triangle, a quadrilateral and a circle.

In this embodiment, the separation pattern 166 is formed by imaginary lines forming a quadrilateral. If the separation pattern 166 has a quadrilateral shape, lengths of multiple separation portions 161 arranged in bar shapes along the second direction Y can be unified, and so lengths of the unit elements of the multiple monitoring transistors 11 can be unified. As a result, variations in characteristics of the multiple monitoring transistors 11 can be suppressed. The separation pattern 166 having a quadrilateral shape has first to fourth edges 166A to 166D. The first to fourth edges 166A to 166D include a first edge 166A, a second edge 166B, a third edge 166C and a fourth edge 166D. The first edge 166A and the second edge 166B extend along the first direction X, and are opposite along the second direction Y. The third edge 166C and the fourth edge 166D extend along the second direction Y, and are opposite along the first direction X.

The separation portion 161 is selectively formed in the gate space 162 of a region surrounded by the separation pattern 166. In this embodiment, the separation portion 161 is formed in each of the gate space 162 sandwiched between one pair of first trench structures 61A and the gate space 162 sandwiched between one pair of second trench structures 61B. Accordingly, the monitoring transistor 11 includes a first system monitoring transistor 12A corresponding to the first system transistor 9A (the first unit transistors 10A) and a second system monitoring transistor 12B corresponding to the second system transistor 9B (the second unit transistors 10B).

The separation portion 161 can also include a first separation portion 161A that electrically isolates the first system transistor 9A and the first system monitoring transistor 12A, and a second separation portion 161B that electrically isolates the second system transistor 9B and the second system monitoring transistor 12B. Accordingly, a portion of the first unit transistors 10A of the first system transistor 9A are insulated and separated into the first unit transistors 10A of the first system monitoring transistor 12A, and a portion of the second unit transistors 10B of the second system transistor 9B are insulated and separated into the second unit transistors 10B of the second system monitoring transistor 12B.

The trench structure 61 includes a first gate structure 167 and a second gate structure 168. The first gate structure 167 and the second gate structure 168, as individually shown on the right of the page of FIG. 22, are predetermined intervals of the trench structure 61 independent from each other. The first gate structure 167 is an interval adjacent to the main body region 163 and the monitoring body region 164 along the first direction X. The second gate structure 168 is an interval adjacent to the separation portion 161 along the first direction X. In other words, a region sandwiched between one pair of first gate structures 167 along the first direction X can also be the main body region 163 or the monitoring body region 164, and a region sandwiched between one pair of second gate structures 168 along the first direction X can also be the separation portion 161.

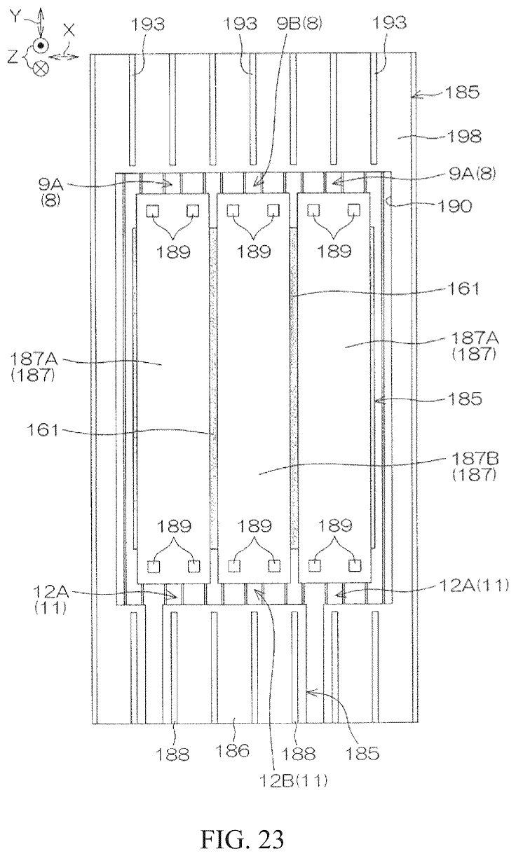

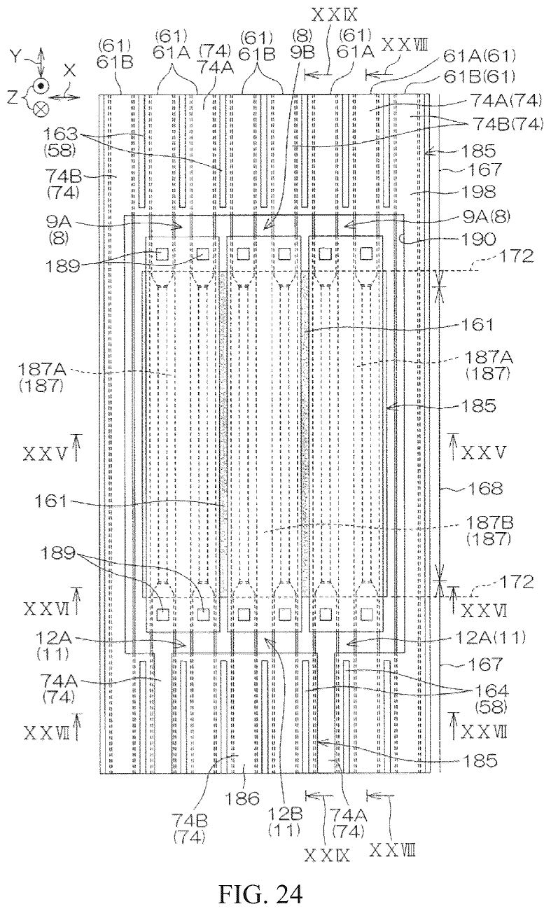

FIG. 23 shows a schematic plan view of a planar structure near the separation portion 161, and indicates a planar shape of a wiring layer 185 used by the main transistor 8 and the monitoring transistor 11. FIG. 24 is a diagram to show the wiring layer 185 in the perspective diagram of FIG. 23. In FIG. 24, an internal structure of the semiconductor device 1 covered by the wiring layer 185 is shown by dotted lines. In FIG. 23 and FIG. 24, a region occupied by the separation portion 161 is shown by regions shaded in gray.

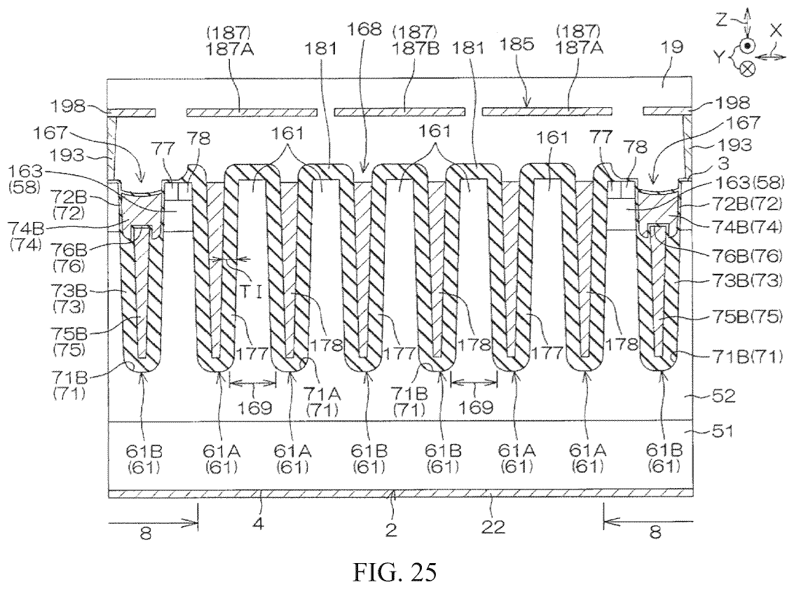

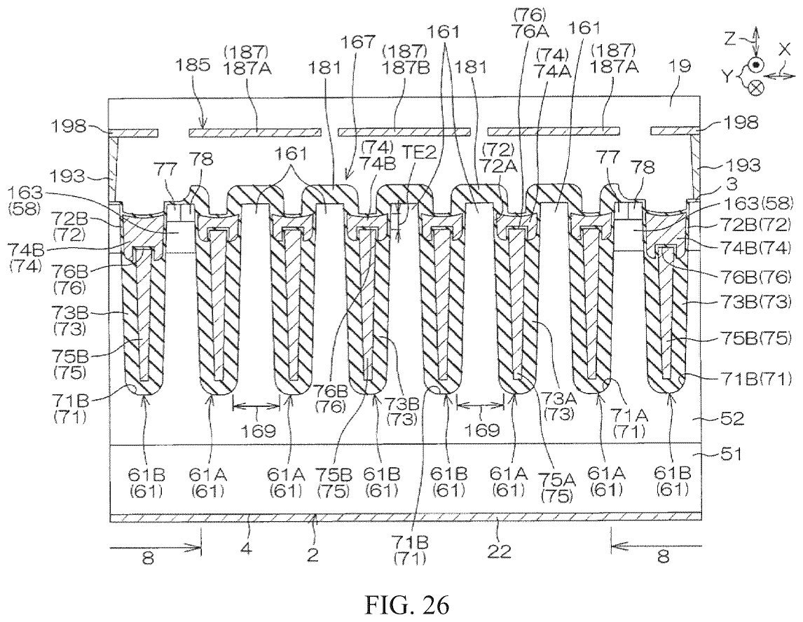

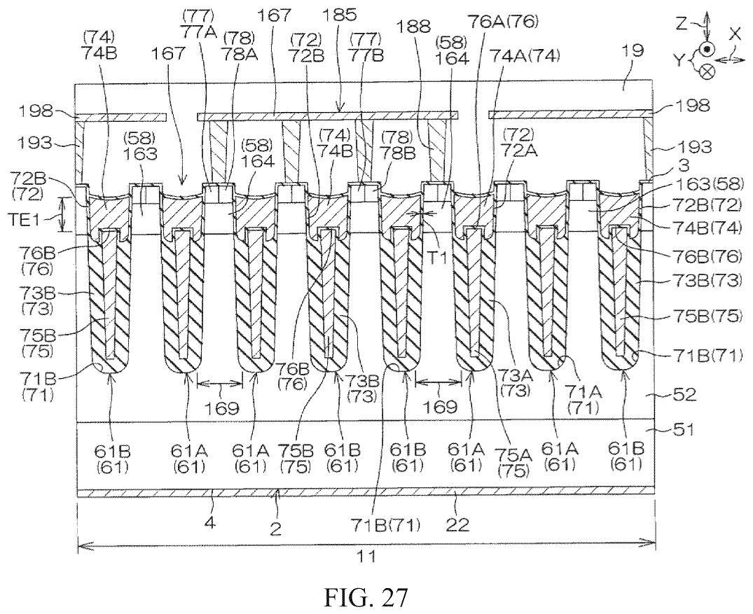

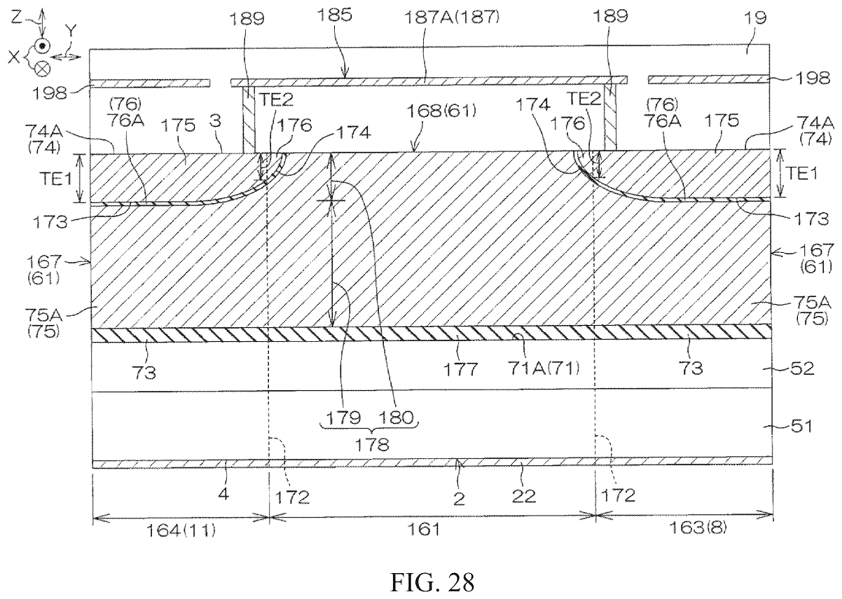

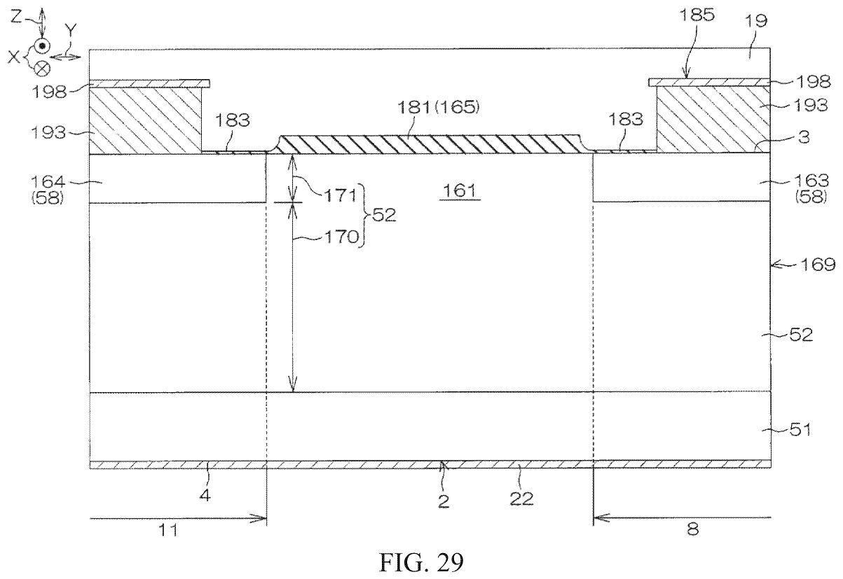

FIG. 25 shows a cross-sectional view along a section line XXV-XXV in FIG. 24. FIG. 26 shows a cross-sectional view along a section line XXVI-XXVI in FIG. 24. FIG. 27 shows a cross-sectional view along a section line XXVII-XXVII in FIG. 24. FIG. 28 shows a cross-sectional view along a section line XXVIII-XXVIII in FIG. 24. FIG. 29 shows a cross-sectional view along a section line XXIX-XXIX in FIG. 24.

Referring to FIG. 25, FIG. 26 and FIG. 29, the separation portion 161 is formed by a portion of the second semiconductor region 52. In this embodiment, the separation portion 161 selectively penetrates the body region 58 from the second main surface 4 toward the first main surface 3 in a mesa 169 that forms the gate space 162. The mesa 169 is a strip-shaped protruding structure of the semiconductor chip 2 sandwiched and hence defined between the adjacent trench structures 61.

For example, when the body region 58 is formed in the second semiconductor region 52 by ion implantation, the separation portion 161 can be formed by covering a region in which the separation portion 161 is to be formed by an etch resist. The region covered by the etch resist remains to serve as the second semiconductor region 52, and so the second semiconductor region 52 can be used as the separation portion 161.

Referring to FIG. 29, for example, the second semiconductor region 52 can be formed throughout the entire semiconductor chip 2, and integrally includes a base region 170 closer to the side of the second main surface 4 than the body region 58, and a protruding portion 171 selectively protruded from the base region 170 in the mesa 169 to the first main surface 3. In this case, the protruding portion 171 of the second semiconductor region 52 can also be the separation portion 161.

Referring to FIG. 25 to FIG. 28, the first gate structure 167 has a multi-electrode structure, and includes the trench 71, the upper insulating film 72, the lower insulating film 73, the upper electrode 74, the lower electrode 75 and the intermediate insulating film 76. The upper electrode 74 of the first gate structure 167 on the side of the main transistor 8 controls the output current IO. The upper electrode 74 of the first gate structure 167 on the side of the monitoring transistor 11 controls the output monitoring current IOM.

As shown in FIG. 22 to FIG. 24 and FIG. 28, the upper electrode 74 of the first gate structure 167 on the side of the main transistor 8 is electrically isolated from the upper electrode 74 of the first gate structure 167 on the side of the monitoring transistor 11 across the second gate structure 168 interposing in between.

The first gate structure 167 has a most portion primarily adjacent to the main body region 163 and the monitoring body region 164 along the first direction X, or can be partially adjacent to the separation portion 161. In this embodiment, referring to FIG. 22 and FIG. 28, the first gate structure 167 can also cross a boundary 172 between the main body region 163 and the monitoring body region 164 with respect to the separation portion 161 along the second direction Y, and is further formed near the boundary 172. The boundary 172 can also be an elongated portion extending from the first edge 166A and the second edge 166B of the separation pattern 166 along the first direction X.

Referring to FIG. 28, the upper electrode 74 of the first gate structure 167 has a thickness continuously decreasing as it crosses the boundary 172 toward the second gate structure 168. For example, a bottom 173 of the upper electrode 74 can also include a sloped portion 174 sloped upward at an end near the boundary 172 toward the second gate structure 168. The sloped portion 174 can also present a cross section in an arc shape raised toward the side of the second main surface 4.

Referring to FIG. 28, in this embodiment, the upper electrode 74 of the first gate structure 167 can also integrally include an upper electrode 175 located on the side of the main body region 163 and the side of the monitoring body region 164 with respect to the boundary 172, and an upper electrode 176 located on the side of the separation portion 161 with respect to the boundary 172. The upper electrode 176 on the side of the separation portion 161 is formed to be thinner than the upper electrode 175 on the side of the main body region 163 and the side of the monitoring body region 164. For example, a thickness TE1 of the upper electrode 175 is preferably between about 5000 Å and about 20000 Å, and more specifically, preferably about 11000 Å.

Referring to FIG. 25 to FIG. 28, the second gate structure 168 has a single-electrode structure, and includes an inner wall insulating film 177 and a single electrode 178.

The inner wall insulating film 177 is formed on an inner wall of the trench 71. More specifically, the inner wall insulating film 177 is formed film-like in an entire region of the inner wall of the trench 71, and defines a recessed space in the trench 71. The inner wall insulating film 177 preferably includes a silicon oxide film. The inner wall insulating film 177 in particular preferably includes a silicon oxide film formed by an oxide of the semiconductor chip 2.

The inner wall insulating film 177 has a thickness TI substantially equivalent to that of the separation insulating film 55 shown in FIG. 13 to FIG. 16. The thickness TI can be between about 0.1 μm and about 1 μm. The thickness TI is preferably between about 0.15 μm and about 0.65 μm. The thickness of a portion of the inner wall insulating film 177 covering the bottom wall of the trench 71 can be less than the thickness of a portion covering the sidewall of the trench 71.

Referring to FIG. 25 and FIG. 26, the inner wall insulating film 177 is formed integrally with the field insulating film 181 in the first main surface 3. Accordingly, a voltage resistant insulating film integrally formed by the inner wall insulating film 177 and the field insulating film 181 covers top corners of the mesa 169. In this embodiment, the separation portion 161 is fixed at a potential same as the first semiconductor region 51, and thus has a higher potential. Thus, by covering the corners on the top of the mesa 169 in which the separation portion 161 is formed by such as a thick insulating film formed by the inner wall insulating film 177 and the field insulating film 181, the withstand voltage can be increased.

The single electrode 178 is buried in the trench 71 in a manner of separation by the inner wall insulating film 177 as an integrated member. In this embodiment, the single electrode 178 includes a conductive polycrystalline silicon. The single electrode 178 is buried from a bottom to a top of the trench 71, and is conducted with the lower electrode 75 of the first gate structure 167 at a lower portion of the trench 71.

In this embodiment, as shown in FIG. 28, the single electrode 178 can also be formed as a portion of a buried lower electrode 75 crossing the first gate structure 167 and the second gate structure 168 along the second direction Y. For example, the lower electrode 75 can also integrally include a base electrode portion 179 buried in the entire trench 71 along the second direction Y, and an electrode protruding portion 180 selectively protruded from the base electrode portion 179 in an interval adjacent to the separation portion 161 to the first main surface 3. In this case, the integral member of the base electrode portion 179 and the electrode protruding portion 180 can also be the single electrode 178.

The thickness TI (referring to FIG. 25) of the inner wall insulating film 177 is thicker than the first thickness T1 (referring to FIG. 27) of the upper insulating film 72, and so the single electrode 178 is formed to be narrower than the upper electrode 74 of the first gate structure 167, as shown in FIG. 22.

As such, the second gate structure 168 is a single-electrode structure same as the trench separation structure 53, and thus the second gate structure 168 can be stably formed by following formation processes of the trench separation structure 53.

For example, the multi-electrode structure of the first gate structure 167 can be obtained by etching the polysilicon filling the trench 71 to midway, and then forming the intermediate insulating film 76 and the upper electrode 74. At this point in time, if the second gate structure 168 is a multi-electrode structure, during etching before the upper insulating film 72 of the first gate structure 167 is formed, adhesiveness between the inner wall insulating film 177 of the second gate structure 168 and the field insulating film 181 may be reduced. The reason behind the above is that, during etching performed as etching on the polysilicon, there are changes in states of surfaces of the inner wall insulating film 177 and the field insulating film 181. As a result, an etch liquid may seep into the trench 71 of the second gate structure 168 to partially remove the inner wall insulating film 177 and the field insulating film 181.

In contrast, if the second gate structure 168 is a single-electrode structure, no changes occur in a state of a surface around the separation pattern 166, and so a decrease in the adhesiveness of the etch resist is suppressed. Thus, the second gate structure 168 can be stably formed.

Referring to FIG. 22, the first gate structure 167 can also have a width reduced portion 184 near the boundary 172. The width reduced portion 184 has a tapered shape in which a width of the first gate structure 167 decreases toward an inside of the separation pattern 166 along the second direction Y in the plan view. With the width reduced portion 184, the width of the gate electrode continuously decreases from the upper electrode 74 of the first gate structure 167 having larger width toward the single electrode 178 of the second gate structure 168 with a smaller width compared to the upper electrode 74. Accordingly, compared to a case when the width of the gate electrode decreases in stages from the first gate structure 167 toward the second gate structure 168, the first gate structure 167 can transition via a moderated sloped surface to the second gate structure 168. As a result, an electric field concentration at the boundary of the first gate structure 167 and the second gate structure 168 can be suppressed.

Referring to FIG. 23 to FIG. 29, the wiring layer 185 is formed within the interlayer insulating layer 19. In addition to the main source wiring 198, the wiring layer 185 can further include a monitoring source wiring 186 and a bridge gate wiring 187.

The monitoring source wiring 186 is connected to the source region 77 and the contact region 78 of the monitoring transistor 11 via a monitoring plug electrode 188 buried in the interlayer insulating layer 19. The monitoring source wiring 186 is electrically connected to the overcurrent protection circuit 17.

Referring to FIG. 23 and FIG. 24, the main source wiring 198 and the monitoring source wiring 186 define a wiring layer formation region 190 used by the bridge gate wiring 187 above the separation portion 161. In the plan view, four corners of the separation portion 161 are surrounded by the main source wiring 198 and the monitoring source wiring 186.

The bridge gate wiring 187 is disposed in the wiring layer formation region 190. The bridge gate wiring 187 crosses the separation portion 161 along the second direction Y, and connects the upper electrode 74 of the first gate structure 167 on the side of the main body region 163 and the upper electrode 74 of the first gate structure 167 on the side of the monitoring body region 164.

Referring to FIG. 28, the bridge gate wiring 187 is connected to each of the upper electrodes 74 via a gate plug electrode 189 buried in the interlayer insulating layer 19. The bridge gate wiring 187 extends from the gate plug electrode 189 on the main side to the gate plug electrode 189 on the monitoring side along the second direction Y in a manner of crossing a region above the separation portion 161. Accordingly, a voltage can also be applied via the bridge gate wiring 187 to the upper electrode 74 on the monitoring side that is electrically isolated from the upper electrode 74 on the main side by the second gate structure 168.

In this embodiment, the bridge gate wiring 187 includes a first gate wiring 187A and a second gate wiring 187B. The first gate wiring 187A connects the main side and the monitoring side of the upper electrode 74A of the first trench structure 61A. The second gate wiring 187B connects the main side and the monitoring side of the upper electrode 74B of the second trench structure 61B.

Each of the first gate wiring 187A and the second gate wiring 187B is independently formed as one in each of one pair of first trench structures 61A and one pair of second trench structures 61B. Accordingly, monitoring currents of the first system monitoring transistor 12A and the second system monitoring transistor 12B can be controlled independently from each other.

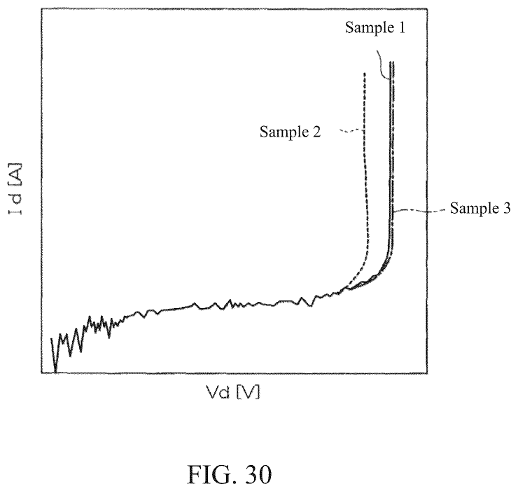

FIG. 30 shows a curve diagram for comparing withstand voltage performance of Sample 1, Sample 2 and Sample 3. In FIG. 30, the horizontal axis represents a source-drain voltage Vd, and the vertical axis represents a source-drain current Id.

In Sample 1 and Sample 2, the main transistor 8 and the monitoring transistor 11 are separated differently. Similar to the description above, Sample 1 employs the separation by means of the separation portion 161 including the n-type impurity region. Sample 2 employs the separation by a stepped trench crossing the strip-like trench structure 61 to substitute for the separation portion 161 for separation. Moreover, Sample 3 is a semiconductor device, and does not include an element for monitoring the current of the main transistor 8, but is not limited to the monitoring transistor 11.

It is learned by comparing the curve diagram of Sample 1 with the curve diagram of Sample 2 in FIG. 30, compared to Sample 2, Sample 1 is broken by a higher voltage. Thus, the separation conducted by separating the monitoring transistor 11 by the separation portion 161, a decrease in the withstand voltage can be suppressed. Moreover, Sample 2 has lower breakdown voltage than Sample 3, while Sample 1 can suppress the withstand voltage from Sample 3 and achieve the same withstand voltage as Sample 3.

The monitoring transistor 11 and the main transistor 8 are formed collectively in the one single first device region 6. Accordingly, monitoring precision can be improved. For example, outside the first device region 6, various structures that affect the monitoring precision are assembled in a monitoring transistor having a structure independent from the main transistor 8. In comparison, the transistor structure same as the monitoring transistor 11 is used in this embodiment, and so the monitoring precision can be improved. Moreover, since only a part of the first device region 6 is used, miniaturization of an element area is also promoted.

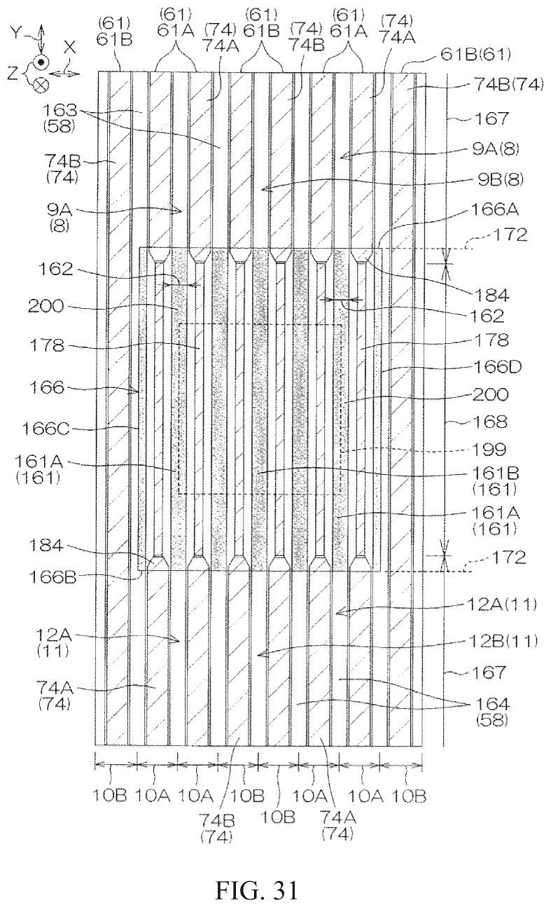

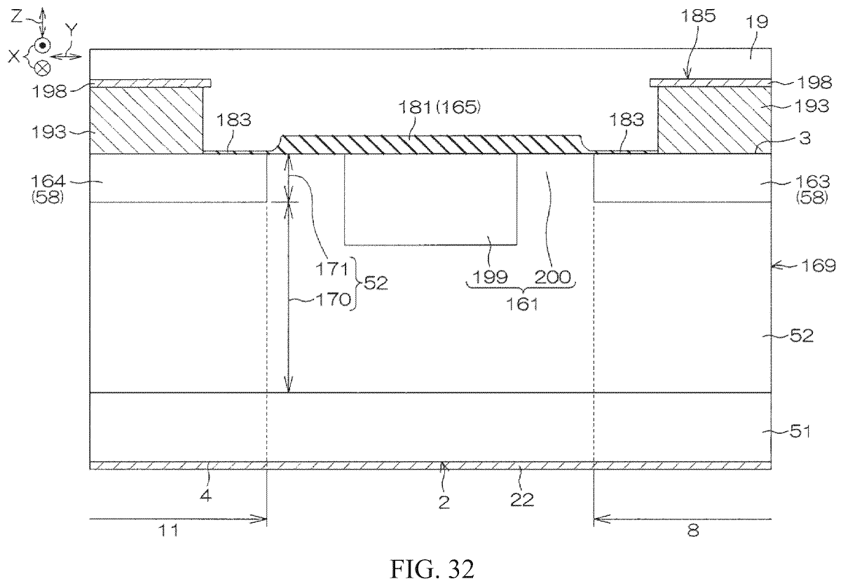

FIG. 31 shows a schematic plan view of a first variation example of the separation portion 161. FIG. 32 shows a schematic cross-sectional view of the first variation example of the separation portion 161. FIG. 31 and FIG. 32 respectively correspond to FIG. 22 and FIG. 29.

In FIG. 31 and FIG. 32, the separation portion 161 includes a high concentration region 199 having an n-type impurity concentration higher than that of the second semiconductor region 52. More specifically, the separation portion 161 includes a base region 200 formed by a portion of the second semiconductor region 52 in contact with the body region 58, and a high concentration region 199 selectively formed in the base region 200. The high concentration region 199 can also be separated from the body region 58. For example, the high concentration region 199 can be formed by selectively implanting an n-type impurity into the base region 200 after the base region 200 is formed in the body region 58.

According to the embodiment above, the main body region 163 and the monitoring body region 164 can be more reliably electrically isolated by disposing the high concentration region 199 between the main body region 163 and the monitoring body region 164. Accordingly, higher withstand voltage can be ensured between the main transistor 8 and the monitoring transistor 11.

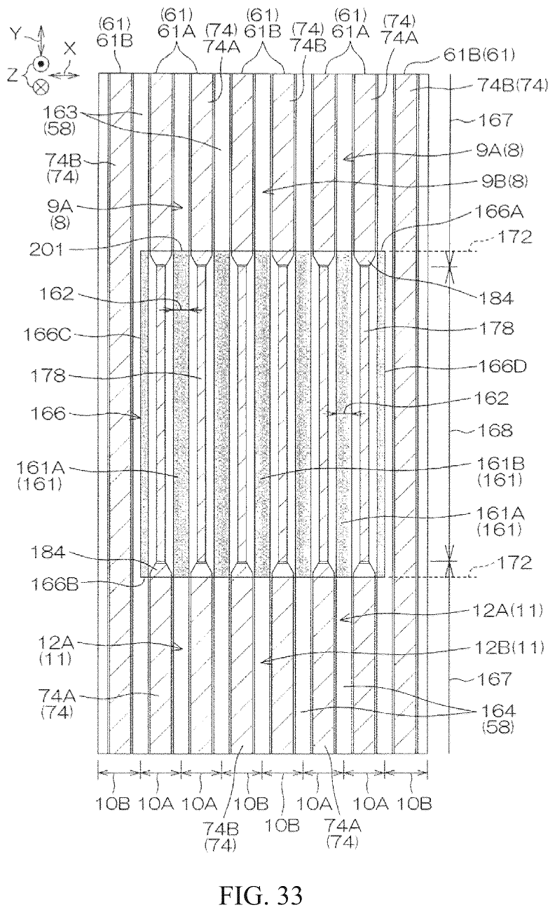

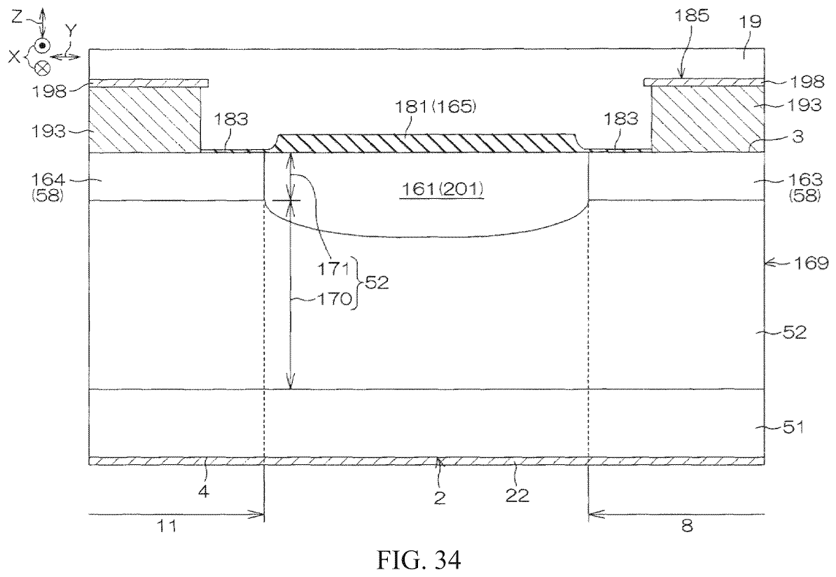

FIG. 33 shows a schematic plan view of a second variation example of the separation portion 161. FIG. 34 shows a schematic cross-sectional view of the second variation example of the separation portion 161. FIG. 33 and FIG. 34 respectively correspond to FIG. 22 and FIG. 29.

In FIG. 33 and FIG. 34, in the separation portion 161, an inside of the separation pattern 166 is entirely formed by a high concentration region 201. The high concentration region 201 is a region having an n-type impurity concentration higher than that of the second semiconductor region 52. The high concentration region 201 is in contact with an entire periphery of the body region 58.

For example, the high concentration region 201 can be formed by the following steps; that is, the body region 58 is formed in the entire first main surface 3 of the semiconductor chip 2, and then an n-type impurity is selectively implanted into the body region 58 through an etch resist having an opening only in a region in which the high concentration region 201 is to be formed. Since the concentration of the high concentration region 201 is higher than that of the body region 58, through an annealing process, the p-type of the body region 58 is replaced by an n-type to form the separation portion 161 (the high concentration region 201).

According to the embodiment above, instead of forming the separation portion 161 by pattern control of the body region 58 regarded as a rough layer, the separation portion 161 (the high concentration region 201) is formed by pattern control of an n-type impurity region regarded as a critical layer. Thus, process margins of the separation portion 161 (the high concentration region 201) can be improved

Moreover, the main body region 163 and the monitoring body region 164 can be more reliably electrically isolated by disposing the high concentration region 201 between the main body region 163 and the monitoring body region 164. Accordingly, higher withstand voltage can be ensured between the main transistor 8 and the monitoring transistor 11.

The embodiments of the present disclosure are described above; however, other implementation forms can also be performed. In the various embodiments, the specific structures of the main transistor 8 of two systems and the monitoring transistor 11 of two systems are described. When the main transistor 8 of n systems is used, each of the n system transistors 9 includes at least one unit element 60. Moreover, when the monitoring transistor 11 of m systems (n systems) is used, each of the m (n) system monitoring transistors 12 includes at least one unit monitoring element. The electrical connections of the n system transistors 9 and the m (n) system monitoring transistors 12 are adjusted by adjusting the numbers or routings of the multiple main source wirings 198, the multiple monitoring source wirings 186 and the multiple main gate wirings 20.

In the embodiments, examples in which the first conductivity type is the n type and the second conductivity type is the p type are described; however, the first conductivity type can also be the p type and the second conductivity type can also be the n type. In this case, a specific configuration can be obtained by substituting a p-type region for an n-type region and substituting an n-type region for a p-type region in the description and the accompanying drawings.

The embodiments of the present disclosure described above are examples in all aspects and are not to be interpreted in a restrictive manner, but are intended to encompass modifications in all aspects. The features recited in the notes below can be extracted from the detailed description and the drawings of the present application. In the description below, alphabets and numerals provided in the parentheses represent the corresponding constituents in the embodiments, and are not intended to limit the scope of the clauses to the embodiments.

### [Note 1-1]

A semiconductor device (1), comprising:
a semiconductor chip (2), having a first main surface (3) in which a first device region (6) is defined;
a first semiconductor region (51) of a first conductivity type, formed in a surface layer of the first device region (6);
a body region (58) of a second conductivity type, formed in a surface layer of the first semiconductor region (51);
a plurality of trench gate structures (61), penetrating the body region (58) and reaching the first semiconductor region (51), and extending along a first direction (X);
a main transistor (8), configured to generate an output current in the body region (58) by controlling the plurality of trench gate structures (61);
a monitoring transistor (11), configured to generate a monitoring current corresponding to the output current in the body region (58) by controlling the plurality of trench gate structures (61); and
a pair of separation portions (161), comprising impurity regions of the first conductivity type selectively formed in a gate space (162) sandwiched between the adjacent trench gate structures (61), and separated along the first direction (X), wherein
the body region (58) is separated by the pair of separation portions (161) into:
   a monitoring body region (164) used by the monitoring transistor (11) and sandwiched between the pair of separation portions (161); and
   a main body region (163) used by the main transistor (8) and located at an opposite side of the monitoring body region (164) across the pair of separation portions (161),
the plurality of trench gate structures (61) include:
   a first gate structure (167) adjacent to the monitoring body region (164) and the main body region (163) along a second direction (Y) intersecting the first direction (X); and
   a second gate structure (168) adjacent to the pair of separation portions (161);
the first gate structure (167) is a multi-electrode structure including an upper electrode (74) and a lower electrode (75) buried in a gate trench (71) in a manner of vertical insulation and separation by an insulator (76), the upper electrode (74) is configured to control the output current, and
the second gate structure (168) is a single-electrode structure in which a single electrode (178) electrically conductive to the lower electrode (75) is buried from a bottom to a top of the gate trench (71).

### [Note 1-2]

The semiconductor device (1) according to Note 1-1, further comprising:
an interlayer insulating layer (19), covering the first main surface (3); and
a bridge gate wiring layer (187), formed within the interlayer insulating layer (19) and crossing the pair of separation portions (161) along the first direction (X), wherein the bridge gate wiring layer (187) connects the upper electrode (74) of the first gate structure (167) on a side of the main body region (163) to the upper electrode (74) of the first gate structure (167) on a side of the monitoring body region (164).

### [Note 1-3]

The semiconductor device (1) according to Note 1-2, further comprising:
a main source wiring layer (198), formed within the interlayer insulating layer (19) and connected to the main body region (163); and
a monitoring source wiring layer (186), connected to the monitor body region (164), wherein
the main source wiring layer (198) and the monitoring source wiring layer (186) define a wiring layer formation region (190) for the bridge gate wiring layer (187) above the pair of separation portions (161).

### [Note 1-4]

The semiconductor device (1) according to any one of Notes 1-1 to 1-3, wherein the first gate structure (167) is formed across a boundary (172) between the pair of separation portions (161) and at least one of the monitoring body region (164) and the main body region (163), and near the boundary (172), and
the upper electrode (74) at a side of the pair of separation portions (161) with respect to the boundary (172) is formed thinner than the upper electrode (74) at at least one of the sides of the monitoring body region (164) and the main body region (163) with respect to the boundary (172).

### [Note 1-5]

The semiconductor device (1) according to Note 1-4, wherein the upper electrode (74) of the first gate structure (167) becomes thinner continuously along the first direction (X) from at least one of the monitoring body region (164) and the main body region (163) toward the pair of separation portions (161).

### [Note 1-6]

The semiconductor device (1) according to any one of Notes 1-1 to 1-5, wherein
the first gate structure (167) includes:
   an upper insulating film (72), formed between the upper electrode (74) and the body region (58); and
   a lower insulating film (73), formed between the lower electrode (75) and the first semiconductor region (51),
the second gate structure (168) includes an inner wall insulating film (177) formed among the single electrode (178), the body region (58) and the first semiconductor region (51), and
each of a thickness of the lower insulating film (73) and a thickness of the inner wall insulating film (177) is greater than a thickness (T1) of the upper insulating film (72).

### [Note 1-7]

The semiconductor device (1) according to Note 1-6, wherein in the inner wall insulating film (177), a thickness of a portion covering an upper sidewall of the gate trench (71) is greater than a thickness of a portion covering a bottom wall of the gate trench (71).

### [Note 1-8]

The semiconductor device (1) according to Note 1-6 or 1-7, further comprising a field insulating film (181) formed on the first main surface (3) and selectively covering the pair of separation portions (161).

### [Note 1-9]

The semiconductor device (1) according to Note 1-8, wherein the field insulating film (181) and the inner wall insulating film (177) form an integral voltage-resistant insulating film covering a top corner of a mesa (169) that forms the gate space (162).

### [Note 1-10]

The semiconductor device (1) according to any one of Notes 1-1 to 1-9, wherein the pair of separation portions (161) are formed by a part of the first semiconductor region (51).

### [Note 1-11]

The semiconductor device (1) according to any one of Notes 1-1 to 1-9, the pair of separation portions (161) include a high concentration region (199, 201) having an impurity concentration of a first conductivity type greater than that of the first semiconductor region (51).

### [Note 1-12]

The semiconductor device (1) according to any one of Notes 1-1 to 1-9, wherein the pair of separation portions (161) include:
a base region (200), formed by a portion of the first semiconductor region (51) in contact with the body region (58); and
a high concentration region (199), selectively formed in the base region (200), separated from the body region (58) via the base region (200), and having an impurity concentration of a first conductivity type greater than that of the base region (200).

### [Note 1-13]

The semiconductor device (1) according to any one of Notes 1-1 to 1-9, wherein the pair of separation portions (161) are formed of a high concentration region (201) having an impurity concentration of a first conductivity type greater than that of the first semiconductor region (51), and are in contact with the body region (58) along at least one of the first direction (X) and the second direction (Y).

### [Note 1-14]

The semiconductor device (1) according to any one of Notes 1-1 to 1-13, further comprising a trench separation structure (53) for defining the first device region (6) in the first main surface (3), wherein
the trench separation structure (53) is a single-electrode structure in which a single isolation electrode (56) is buried from a bottom to a top of a separation trench (54).

### [Note 1-15]

The semiconductor device (1) according to any one of Notes 1-1 to 1-14, wherein
the main transistor (8) includes:
   a first system transistor (9A), configured to generate a first system current as a part of the output current; and
   a second system transistor (9B), independent of the first system transistor (9A) and configured to generate a second system current as a part of the output current, and
the monitoring transistor (11) includes:
   a first system monitoring transistor (12A), configured to generate a first system monitoring current corresponding to the first system current; and
   a second system monitoring transistor (12B), configured to generate a second system monitoring current corresponding to the second system current.

1. A semiconductor device, comprising:
a semiconductor chip, having a first main surface in which a first device region is defined;
a first semiconductor region of a first conductivity type, formed in a surface layer of the first device region;
a body region of a second conductivity type, formed in a surface layer of the first semiconductor region;
a plurality of trench gate structures, penetrating the body region and reaching the first semiconductor region, and extending along a first direction;
a main transistor, configured to generate an output current in the body region by controlling the plurality of trench gate structures;
a monitoring transistor, configured to generate a monitoring current corresponding to the output current in the body region by controlling the plurality of trench gate structures; and
a pair of separation portions, comprising impurity regions of the first conductivity type selectively formed in a gate space sandwiched between the adjacent trench gate structures, and separated along the first direction, wherein
the body region is separated by the pair of separation portions into:
a monitoring body region used by the monitoring transistor and sandwiched between the pair of separation portions; and
a main body region used by the main transistor and located at an opposite side of the monitoring body region across the pair of separation portions,
the plurality of trench gate structures include:
a first gate structure adjacent to the monitoring body region and the main body region along a second direction intersecting the first direction; and
a second gate structure adjacent to the pair of separation portions,
the first gate structure is a multi-electrode structure including an upper electrode and a lower electrode buried in a gate trench in a manner of vertical insulation and separation by an insulator, the upper electrode is configured to control the output current, and
the second gate structure is a single-electrode structure in which a single electrode electrically conductive to the lower electrode is buried from a bottom to a top of the gate trench.

2. The semiconductor device of claim 1, further comprising:
an interlayer insulating layer, covering the first main surface; and
a bridge gate wiring layer, formed within the interlayer insulating layer and crossing the pair of separation portions along the first direction, wherein the bridge gate wiring layer connects the upper electrode of the first gate structure on a side of the main body region to the upper electrode of the first gate structure on a side of the monitoring body region.

3. The semiconductor device of claim 2, further comprising:
a main source wiring layer, formed within the interlayer insulating layer and connected to the main body region; and
a monitoring source wiring layer, connected to the monitor body region, wherein
the main source wiring layer and the monitoring source wiring layer define a wiring layer formation region for the bridge gate wiring layer above the pair of separation portions.

4. The semiconductor device of claim 1, wherein the first gate structure is formed
across a boundary between the pair of separation portions and at least one of the monitoring body region and the main body region, and
near the boundary, and
the upper electrode at a side of the pair of separation portions with respect to the boundary is formed thinner than the upper electrode at at least one of the sides of the monitoring body region and the main body region with respect to the boundary.

5. The semiconductor device of claim 2, wherein the first gate structure is formed
across a boundary between the pair of separation portions and at least one of the monitoring body region and the main body region, and
near the boundary, and
the upper electrode at a side of the pair of separation portions with respect to the boundary is formed thinner than the upper electrode at at least one of the sides of the monitoring body region and the main body region with respect to the boundary.

6. The semiconductor device of claim 3, wherein the first gate structure is formed
across a boundary between the pair of separation portions and at least one of the monitoring body region and the main body region, and
near the boundary, and
the upper electrode at a side of the pair of separation portions with respect to the boundary is formed thinner than the upper electrode at at least one of the sides of the monitoring body region and the main body region with respect to the boundary.

7. The semiconductor device of claim 4, wherein the upper electrode of the first gate structure becomes thinner continuously along the first direction from at least one of the monitoring body region and the main body region toward the pair of separation portions.

8. The semiconductor device of claim 1, wherein
the first gate structure includes:
an upper insulating film, formed between the upper electrode and the body region; and
a lower insulating film, formed between the lower electrode and the first semiconductor region,
the second gate structure includes an inner wall insulating film formed among the single electrode, the body region and the first semiconductor region, and
each of a thickness of the lower insulating film and a thickness of the inner wall insulating film is greater than a thickness of the upper insulating film.

9. The semiconductor device of claim 2, wherein
the first gate structure includes:
an upper insulating film, formed between the upper electrode and the body region; and
a lower insulating film, formed between the lower electrode and the first semiconductor region,
the second gate structure includes an inner wall insulating film formed among the single electrode, the body region and the first semiconductor region, and
each of a thickness of the lower insulating film and a thickness of the inner wall insulating film is greater than a thickness of the upper insulating film.

10. The semiconductor device of claim 3, wherein
the first gate structure includes:
an upper insulating film, formed between the upper electrode and the body region; and
a lower insulating film, formed between the lower electrode and the first semiconductor region,
the second gate structure includes an inner wall insulating film formed among the single electrode, the body region and the first semiconductor region, and
each of a thickness of the lower insulating film and a thickness of the inner wall insulating film is greater than a thickness of the upper insulating film.

11. The semiconductor device of claim 8, wherein in the inner wall insulating film, a thickness of a portion covering an upper sidewall of the gate trench is greater than a thickness of a portion covering a bottom wall of the gate trench.

12. The semiconductor device of claim 8, further comprising a field insulating film formed on the first main surface and selectively covering the pair of separation portions.

13. The semiconductor device of claim 12, wherein the field insulating film and the inner wall insulating film form an integral voltage-resistant insulating film covering a top corner of a mesa that forms the gate space.

14. The semiconductor device of claim 1, wherein the pair of separation portions are formed by a part of the first semiconductor region.

15. The semiconductor device of claim 2, wherein the pair of separation portions are formed by a part of the first semiconductor region.

16. The semiconductor device of claim 1, wherein the pair of separation portions include a high concentration region having an impurity concentration of a first conductivity type greater than that of the first semiconductor region.

17. The semiconductor device of claim 1, wherein the pair of separation portions include:
a base region, formed by a portion of the first semiconductor region in contact with the body region; and
a high concentration region, selectively formed in the base region, separated from the body region via the base region, and having an impurity concentration of a first conductivity type greater than that of the base region.

18. The semiconductor device of claim 1, wherein the pair of separation portions are formed of a high concentration region having an impurity concentration of a first conductivity type greater than that of the first semiconductor region, and are in contact with the body region along at least one of the first direction and the second direction.

19. The semiconductor device of claim 1, further comprising a trench separation structure for defining the first device region in the first main surface, wherein the trench separation structure is a single-electrode structure in which a single isolation electrode is buried from a bottom to a top of a separation trench.

20. The semiconductor device of claim 1, wherein
the main transistor includes:
a first system transistor, configured to generate a first system current as a part of the output current; and
a second system transistor, independent of the first system transistor and configured to generate a second system current as a part of the output current, and
the monitoring transistor includes:
a first system monitoring transistor, configured to generate a first system monitoring current corresponding to the first system current; and
a second system monitoring transistor, configured to generate a second system monitoring current corresponding to the second system current.
